(19) United States
(12) Patent Application Publication
(10) Pub. No.: US 2026/0096089 A1
(43) Pub. Date: Apr. 2, 2026

(54) SEMICONDUCTOR DEVICE AND METHOD OF FABRICATING THE SAME

(71) Applicant: Samsung Electronics Co., Ltd., Suwon-si (KR)

(72) Inventors: Kyooho JUNG, Suwon-si (KR); Donghyun KIM, Suwon-si (KR); Jooho LEE, Suwon-si (KR); Duk Hyun CHOE, Suwon-si (KR)

(73) Assignee: Samsung Electronics Co., Ltd., Suwon-si (KR)

(21) Appl. No.: 19/289,837

(22) Filed: Aug. 4, 2025

(30) Foreign Application Priority Data
Sep. 27, 2024 (KR) 10-2024-0132212

(51) Int. Cl. H10B 12/00; H10D 1/68

(52) U.S. Cl. CPC H10B 12/315; H10B 12/033; H10B 12/482; H10B 12/488; H10B 12/50; H10D 1/716

(57) ABSTRACT

Provided is a semiconductor device including a first electrode extending in a first direction on a substrate, a capping film covering a first surface of the first electrode intersecting with the first direction, a dielectric film surrounding a second surface of the first electrode intersecting with the first surface, and a second electrode covering the capping film and the dielectric film.

### CROSS-REFERENCE TO RELATED APPLICATIONS

This application claims the benefit of Korean Patent Application No. 10-2024-0132212, filed on Sep. 27, 2024, in the Korean Intellectual Property Office, the disclosure of which is incorporated herein by reference in its entirety.

### BACKGROUND

### 1. Field of the Invention

Example embodiments relate to a semiconductor device and a method of fabricating the same.

### 2. Description of the Related Art

Recently, demand for semiconductor devices having higher capacity and higher integration has increased; accordingly, the dimensions of design rules continue to be reduced. Such trends also emerge in dynamic random access memory (DRAM), an example of the semiconductor devices. To operate a DRAM device, a predetermined level or more of capacitance is designed for each single cell.

Increases in capacitance lead to increases in an amount of charge stored in a capacitor, thereby improving a refresh characteristic of such semiconductor devices. The improved refresh characteristic of semiconductor devices may improve a yield of semiconductor devices.

As a critical dimension of capacitors decreases due to demand for the higher integration of semiconductor devices and the height of capacitors increases for capacitance enhancement, the difficulty level of forming capacitors increases.

### SUMMARY

An aspect provides a semiconductor device of which the difficulty of a fabricating process is improved and a method of fabricating the same.

Another aspect provides a semiconductor device of which capacitance is enhanced and a method of fabricating the same.

Example embodiments are not limited to the technical features described above, and other unstated technical features may be made apparent to those skilled in the art from the following description.

According to an aspect, there is provided a semiconductor device including a first electrode extending in a first direction; a capping film covering a first surface of the first electrode, the first surface intersecting with the first direction; a dielectric film surrounding a second surface of the first electrode, the second surface intersecting with the first surface; and a second electrode covering the capping film and the dielectric film.

According to another aspect, there is provided a method of fabricating a semiconductor device, the method including forming a trench penetrating a mold structure in a first direction, forming a dielectric film on an inner sidewall of the trench, forming a first electrode on the dielectric film within the trench, forming a capping film covering the first electrode within the trench, removing at least a portion of the mold structure, and forming a second electrode on the dielectric film and the capping film.

According to another aspect, there is provided a semiconductor device including a first electrode extending in a first direction; a capping film covering a first surface of the first electrode, the first surface intersecting with the first direction, a dielectric film covering a second surface of the first electrode, the second surface intersecting with the first surface; a second electrode covering the capping film and the dielectric film, and a plurality of supporters spaced apart in the first direction and connected to the dielectric film. The dielectric film may separate the first electrode from the plurality of supporters, the second electrode may fill a space between the plurality of supporters, and the plurality of supporters may be non-overlapping with the dielectric film in the first direction.

Additional aspects of example embodiments will be set forth in part in the description which follows and, in part, will be apparent from the description.

According to example embodiments of the present disclosure, it is possible to improve a fabricating process of a semiconductor device by reducing the difficulty of the process.

According to example embodiments of the present disclosure, it is possible to enhance capacitance of a semiconductor device.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is an example diagram for illustrating a semiconductor device according to some example embodiments;

FIG. 2 is an example diagram for illustrating a semiconductor device according to some other example embodiments;

FIG. 3 is an example diagram for illustrating a semiconductor device according to still other example embodiments;

FIG. 4 is an example diagram for illustrating a semiconductor device according to yet other example embodiments;

FIGS. 5 to 11 are example diagrams showing intermediate stages for illustrating a method of fabricating a semiconductor device according to some example embodiments;

FIG. 12 is a schematic layout diagram for illustrating a semiconductor device according to some example embodiments;

FIG. 13 is an example diagram showing a cross-section taken along line A-A of FIG. 12;

FIG. 14 is an example diagram showing a cross-section taken along line B-B of FIG. 12;

FIG. 15 is a schematic layout diagram for illustrating a semiconductor device according to some other example embodiments;

FIG. 16 is an example diagram showing a cross-section taken along line A-A of FIG. 15;

FIG. 17 is an example diagram showing a cross-section taken along line B-B of FIG. 15;

FIG. 18 is a schematic layout diagram for illustrating a semiconductor device according to still other example embodiments;

FIG. 19 is an example diagram showing a cross-section taken along line A-A of FIG. 18; and

FIG. 20 is another example diagram showing a cross-section taken along line A-A of FIG. 18 to illustrate a semiconductor device according to yet other example embodiments.

### DETAILED DESCRIPTION

Before describing example embodiments in detail, the words and terminologies used in the specification and claims are not to be construed as limited to common or dictionary meanings but construed as meanings and conceptions coinciding with the technical spirit of the present disclosure under a principle that the inventor(s) may appropriately define the conception of the terminologies to explain the invention. Therefore, the example embodiments described in the specification and the configurations illustrated in the drawings are example embodiments of the present disclosure and do not fully cover the spirit of the present disclosure. Accordingly, it should be understood that there may be various equivalents and modifications that may replace those when this application is filed.

In the descriptions below, a singular expression includes a plural expression unless apparently otherwise defined by context. It should be understood that terms such as “comprise or include” and “consist of” are intended to indicate the presence of a feature, a number, a step, an operation, an element, a component, or a combination thereof which are described in the specification and not intended to previously exclude the possibility of the presence or addition of one or more other features, numbers, steps, operations, elements, components, or combinations thereof.

In the present disclosure, a singular expression includes a plural expression unless apparently otherwise defined by context. In addition, although the terms “first”, “second”, etc. may be used to describe various elements, these elements should not be limited by the above terms, and the terms may be used to distinguish one element from another. Within the scope of the present disclosure, a first element may be referred to as a second element, and similarly, a second element may be referred to as a first element. Further, the shape or size of elements in the accompanying drawings may be exaggerated for clearer description.

In addition, expressions such as upper side, upper portion, lower side, lower portion, side surface, front surface, and rear surface hereinafter are represented based on a direction illustrated in a drawing and may be represented otherwise when the direction of a corresponding object changes. In other words, such spatially relative terms are intended to encompass different orientations of the device in use or operation in addition to the orientation depicted in the figures, and that the device may be otherwise oriented (rotated 90 degrees or at other orientations) and the spatially relative terms used herein interpreted accordingly. The shape or size of elements in drawings may be exaggerated for clearer description. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Hereinafter, example embodiments of the present disclosure will be described with reference to the accompanying drawings.

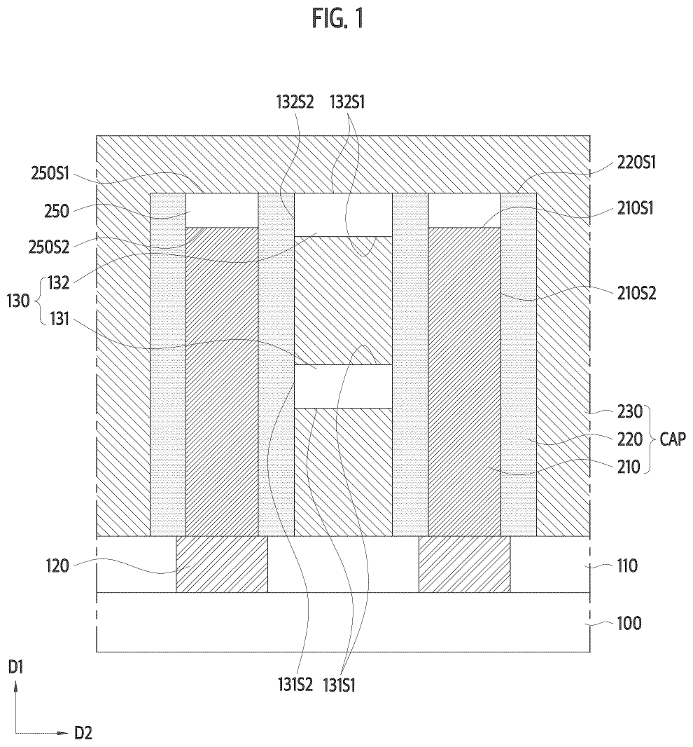

FIG. 1 is an example diagram for illustrating a semiconductor device according to some example embodiments.

Referring to FIG. 1, the semiconductor device according to some example embodiments includes a substrate 100, an interlayer insulating film 110, an electrode connection structure 120, a capacitor structure CAP, and a supporter structure 130.

According to some example embodiments, the substrate 100 may include an elemental and/or a compound semiconductor. For example, the substrate 100 may be (or include) bulk silicon and/or silicon-on-insulator (SOI). In at least some embodiments, the substrate 100 may be a silicon substrate and/or may include, but is not limited to, other materials such as one or more of silicon germanium, silicon germanium on insulator (SGOI), indium antimonide, lead telluride, indium arsenide, indium phosphide, gallium arsenide, gallium antimonide and/or the like.

According to some example embodiments, the interlayer insulating film 110 may be disposed on the substrate 100. The interlayer insulating film 110 may surround the electrode connection structure 120. FIG. 1 illustrates that the interlayer insulating film 110 is in direct contact with the substrate 100 and formed on the substrate 100, but the example embodiments are not limited thereto. For example, in at least some embodiments, other structures may also be disposed between the interlayer insulating film 110 and the substrate 100.

According to some example embodiments, the interlayer insulating film 110 may include an electrically insulating material, for example, at least one of silicon oxide, silicon nitride, silicon oxynitride (SiON), silicon oxycarbonitride (SiOCN), a combination thereof, and/or the like.

According to some example embodiments, the electrode connection structure 120 may be disposed on the substrate 100. The electrode connection structure 120 may be connected to the substrate 100. The electrode connection structure 120 may be electrically connected to a conductive region formed on and/or within the substrate 100. The electrode connection structure 120 may be disposed within the interlayer insulating film 110.

According to some example embodiments, the electrode connection structure 120 includes an electrically conductive material, such as one or more of an impurity-doped semiconductor material, a conductive metal nitride (for example, titanium nitride, tantalum nitride, niobium nitride, or tungsten nitride), a metal (for example, ruthenium, iridium, titanium, or tantalum), a conductive metal oxide (for example, iridium oxide or niobium oxide), and/or the like.

According to some example embodiments, the capacitor structure CAP may be disposed on the electrode connection structure 120. The capacitor structure CAP may be electrically connected to the electrode connection structure 120.

According to some example embodiments, the capacitor structure CAP includes a first electrode 210, a dielectric film 220, and a second electrode 230.

According to some example embodiments, the first electrode 210 may be disposed on the electrode connection structure 120. The first electrode 210 may be electrically connected to the electrode connection structure 120. The first electrode 210 may overlap with the electrode connection structure 120 in a first direction D1 (e.g. a vertical direction). The first electrode 210 may be surrounded by the dielectric film 220. The first electrode 210 may be covered by the dielectric film 220 and a capping film 250.

According to some example embodiments, the first electrode 210 extends in the first direction D1 on the substrate 100. A length of the first electrode 210 extending in the first direction D1 may be greater than a width of the first electrode 210 in a second direction D2 (e.g. a horizontal direction). In these cases, the second direction D2 may be a direction perpendicular to the first direction D1 while being parallel with a surface of the substrate 100. In other words, an extension length of a second surface 210S2 of the first electrode based on the first direction D1 may be greater than a width of a first surface 210S1 of the first electrode based on the second direction D2. The first electrode 210 may have, for example, a pillar shape. In at least one embodiment, the length of the first electrode 210 extending in the first direction D1 may be less than a length of the dielectric film 220 extending in the first direction D1. Based on the substrate 100, a first surface 210S1 of the first electrode may be disposed below a first surface 220S1 (e.g. an upper surface) of the dielectric film. The first surface 210S1 of the first electrode may also be referred to as being disposed to be more adjacent to the substrate 100 than the first surface 220S1 of the dielectric film.

According to some example embodiments, FIG. 1 illustrates that the width of the first electrode 210 based on the second direction D2 is less than a width of the electrode connection structure 120, but the example embodiments are not limited thereto. For example, according to some example embodiments, the width of the first electrode 210, based on the second direction D2, may also be greater than the width of the electrode connection structure 120.

According to some example embodiments, the first electrode 210 may include the first surface 210S1 and a second surface 210S2. The first surface 210S1 of the first electrode may intersect with the first direction D1. For example, the first surface 210S1 of the first electrode may vertically intersect with the first direction D1. The first surface 210S1 of the first electrode may be disposed on a plane defined by the second direction D2 intersecting with the first direction D1. For example, the first surface 210S1 of the first electrode may be disposed opposite to the substrate 100 based on the first direction D1. For example, the first surface 210S1 of the first electrode may form an upper surface of the first electrode 210 based on the substrate 100 as the reference.

According to some example embodiments, the second surface 210S2 of the first electrode may intersect with the first surface 210S1 of the first electrode. The second surface 210S2 of the first electrode may vertically intersect with the first surface 210S1 of the first electrode. The second surface 210S2 of the first electrode may extend in the first direction D1. For example, the second surface 210S2 of the first electrode may form a side surface of the first electrode 210.

According to some example embodiments, the first surface 210S1 of the first electrode may overlap with the capping film 250 in the first direction D1. The first surface 210S1 of the first electrode may be covered by the capping film 250. According to some embodiments, first surface 210S1 of the first electrode does not overlap with the dielectric film 220 in the first direction D1. The second surface 210S2 of the first electrode may overlap with the dielectric film 220 in the second direction D2. The second surface 210S2 of the first electrode may be covered by the dielectric film 220. An entire portion of the second surface 210S2 of the first electrode may be in contact with the dielectric film 220.

According to some example embodiments, the first electrode 210 includes an electrically conductive material. For example, the first electrode 210 may include, but is not limited to, one or more of a doped semiconductor material, a conductive metal nitride (for example, titanium nitride, tantalum nitride, niobium nitride, or tungsten nitride), a metal (for example, ruthenium, iridium, titanium, or tantalum), a conductive metal oxide (for example, iridium oxide or niobium oxide), and/or the like.

According to some example embodiments, the dielectric film 220 may surround the first electrode 210. The dielectric film 220 may surround the second surface 210S2 of the first electrode. The dielectric film 220 may cover the entire portion of the second surface 210S2 of the first electrode. The dielectric film 220 may extend in the first direction D1 on the second surface 210S2 of the first electrode. According to some example embodiments, the dielectric film 220 does not overlap with the first electrode 210 in the first direction D1. For example, according to some example embodiment, the dielectric film 220 does not cover the first surface 210S1 of the first electrode in the first direction D1. The dielectric film 220 may be connected to the supporter structure 130. The dielectric film 220 may be in contact with the supporter structure 130 on a surface facing in a direction (for example, the second direction D2) intersecting with the first direction D1.

According to some example embodiments, the dielectric film 220 includes an electrically insulating material. The dielectric film 220 may include, for example, one or more of silicon oxide, silicon nitride, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof but is not limited thereto. The dielectric film 220 is illustrated as a single layer; but is not limited thereto. For example, the dielectric film 220 may include one or more layers.

According to some example embodiments, the dielectric film 220 may include a ferroelectric material. For example, the dielectric film 220 may include at least one of AlScN, AlBN, AlGaN, AlInN, AlYN, doped AlN, ZrHfON, AlHfON, and/or YHfON having a ferroelectric phase. According to some alternative example embodiments, the dielectric film 220 may consist of SiO, TaO, TaAlO, TaON, AlO, AlSiO, HfO, HfSiO, ZrO, RuO, WO, HfZrO, ZrSiO, TiO, TiAlO, VO, NbO, MoO, MnO, LaO YO, CoO, NiO, CuO, ZnO, FeO, SrO, BaO, BST((Ba, Sr)TiO), STO(SrTiO), BTO(BaTiO), PTO(PbTiO), AgNbO, BiFeO, PZT(Pb(Zr, Ti)O), (Pb, La)(Zr, Ti)O, Ba(Zr, Ti)O, Sr(Zr, Ti)O, or a combination thereof. For example, the dielectric film 220 may include at least one of hafnium oxide (for example, HfO2) and hafnium-zirconium oxide (for example, Hf0.5Zr0.5O2), but example embodiments are not limited thereto.

According to some example embodiments, the dielectric film 220 may include a ferroelectric nitride. For example, the dielectric film 220 may include one or more of hafnium nitride and/or hafnium-zirconium nitride.

According to some example embodiments, the dielectric film 220 may include a high-permittivity material. The high-permittivity material may include, for example, at least one of HfON, ZrON, SiN, AlScN, AlBN, and CaTiN. For another example, the high-permittivity material may include at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and/or a combination thereof.

According to some example embodiments, the second electrode 230 may be disposed on the dielectric film 220 and the capping film 250. The second electrode 230 may cover the dielectric film 220 and the capping film 250. The second electrode 230 may extend along profiles of the dielectric film 220 and the capping film 250. The second electrode 230 is illustrated as a single layer; but is not limited thereto. For example, the second electrode 230 may include one or more layers.

According to some example embodiments, the second electrode 230 may surround the supporter structure 130. The second electrode 230 may be in direct contact with the supporter structure 130. The second electrode 230 may cover first surfaces 131S1 and 132S1 of the supporter structure which are stacked in the first direction D1. The second electrode 230 may be in contact with the first surfaces 131S1 and 132S1 of the supporter structure which are disposed in the first direction D1.

According to some example embodiments, the second electrode 230 may fill a space between a first supporter 131 and a second supporter 132 along the first direction D1. For example, the second electrode 230 may fill a space between the first surface 131S1 of the first supporter and the first surface 132S1 of the second supporter which face each other. The second electrode 230 may be surrounded by the first surface 131S1 of the first supporter and the first surface 132S1 of the second supporter which face each other in the first direction D1.

According to some example embodiments, at least one surface of the second electrode 230 may be disposed on the same plane with at least one surface of each of the first electrode 210 and the dielectric film 220. For example, a lower surface of the second electrode 230 in contact with the interlayer insulating film 110 may be disposed on the same plane with a lower surface of the first electrode 210 disposed opposite to the first surface 210S1 of the first electrode in the first direction D1 and a lower surface of the dielectric film 220 disposed opposite to the first surface 220S1 of the dielectric film in the first direction D1.

According to some example embodiments, the second electrode 230 includes an electrically conductive material, for example, a doped semiconductor material, a conductive metal nitride (for example, titanium nitride, tantalum nitride, niobium nitride, or tungsten nitride), a metal (for example, ruthenium, iridium, titanium, or tantalum), and a conductive metal oxide (for example, iridium oxide or niobium oxide), and/or the like. In the semiconductor device according to some example embodiments, the second electrode 230 may include titanium nitride (TiN). Further, in the semiconductor device according to some example embodiments, the second electrode 230 may include niobium nitride (NbN).

According to some example embodiments, the supporter structure 130 may include the first supporter 131 and the second supporter 132. The supporter structure 130 may connect and support the first electrode 210 and the dielectric film 220 surrounding the first electrode 210 which are disposed in the second direction D2. The supporter structure 130 may be connected to the dielectric film 220 and surrounded by the dielectric film 220 and the second electrode 230. According to some example embodiments, first supporter 131 and the second supporter 132 do not overlap with the dielectric film 220 in the first direction D1.

According to some example embodiments, the first supporter 131 may be disposed above the interlayer insulating film 110. The first supporter 131 may be spaced apart from the interlayer insulating film 110 in the first direction D1. The first supporter 131 may be spaced apart from the first electrode 210. The first supporter 131 may be spaced apart from the second surface 210S2 of the first electrode. The first supporter 131 may be connected to the dielectric film 220. The first supporter 131 may be spaced apart from the first electrode 210 with the dielectric film 220 in between. The first supporter 131 may not be in contact with the first electrode 210.

According to some example embodiments, the second supporter 132 may be disposed above the first supporter 131. The second supporter 132 may be spaced apart from the first supporter 131 in the first direction D1. The second supporter 132 may be spaced apart from the first electrode 210. The second supporter 132 may be spaced apart from the second surface 210S2 of the first electrode. The second supporter 132 may be connected to the dielectric film 220. The second supporter 132 may be spaced apart from the first electrode 210 with the dielectric film 220 in between. The second supporter 132 may not be in contact with the first electrode 210.

FIG. 1 illustrates that 2 of the first electrodes 210 and the dielectric films 220 which are adjacent in the second direction D2 are connected by the first supporter 131 and the second supporter 132; however, the example embodiments are not limited thereto.

According to some example embodiments, one of the first surface 132S1 of the second supporter may be disposed on the same plane with a first surface 250S1 of the capping film. For example, an upper surface of the first surface 132S1 of the second supporter may be disposed on the same plane with the first surface 250S1 of the capping film. However, the example embodiments are not limited thereto. For example, the first surface 250S1 of the capping film may protrude further in the first direction D1 away from the substrate 100 than the upper surface of the first surface 132S1 of the second supporter.

According to some example embodiments, second surfaces 131S2 and 132S2 of the supporter structure, which are disposed in the second direction D2 intersecting with the first direction D1, are in contact with the dielectric film. Specifically, the second surfaces 131S2 and 132S2 intersecting with the first surfaces 131S1 and 132S1 of the supporter structure 130 may be in contact with the dielectric film 220. The second surfaces 131S2 and 132S2 of the supporter structure 130 may be in contact with and connected to the dielectric film 220. The second surfaces 131S2 and 132S2 of the supporter structure 130 may be spaced apart from the first electrode 210 with the dielectric film 220 in between. The second surfaces 131S2 and 132S2 of the supporter structure 130 may not be in contact with the first electrode 210.

According to some example embodiments, each of the first supporter 131 and the second supporter 132 may include an electrically insulating material, for example, at least one of silicon nitride (SiN), silicon carbonitride (SiCN), silicon boron nitride (SiBN), silicon carbon oxide (SiCO), silicon oxynitride (SiON), silicon oxide (SiO), and silicon oxycarbonitride (SiOCN). In the semiconductor device according to some example embodiments, each of the first supporter 131 and the second supporter 132 may include silicon carbonitride (SiCN) or silicon nitride.

FIG. 1 illustrates that a thickness of the first supporter 131 in the first direction D1 is the same as (or substantially similar to) a thickness of the second supporter 132 in the first direction D1, but example embodiments are not limited thereto. The thickness of the first supporter 131 in the first direction D1 may also be less than the thickness of the second supporter 132 in the first direction D1.

Unlike what is illustrated, the semiconductor device according to some example embodiments may also include one of the first supporter 131 and the second supporter 132. Alternatively, the semiconductor device according to some example embodiments may also include an additional supporter pattern disposed between the interlayer insulating film 110 and the first supporter 131 and/or between the first supporter 131 and the second supporter 132.

According to some example embodiments, the capping film 250 is disposed on the first electrode 210. The capping film 250 may cover the first surface 210S1 of the first electrode. A second surface 250S2 of the capping film may be in contact with the first surface 210S1 of the first electrode. In the first direction D1, the capping film 250 may be disposed between the first electrode 210 and the second electrode 230.

According to some example embodiments, at least a portion of the capping film 250 may be surrounded by the dielectric film 220. The dielectric film 220 may surround a sidewall of the capping film 250 connecting the first surface 250S1 and the second surface 250S2 of the capping film.

According to some example embodiments, the first surface 250S1 of the capping film may be disposed on the same plane with the first surface 220S1 of the dielectric film. The first surface 250S1 of the capping film may be a surface disposed opposite to the second surface 250S2 of the capping film based on the first direction D1. The second surface 250S2 of the capping film may be a surface that faces the first electrode 210 and is in contact with the first surface 210S1 of the first electrode.

According to some example embodiments, in the first direction D1, the capping film 250 overlaps with the first electrode 210 and does not overlap with the dielectric film 220. In the first direction D1, the capping film 250 may cover the first electrode 210 but may not cover the dielectric film 220. Based on the second direction D2 intersecting with the first direction D1, a width of the capping film 250 may be the same as or substantially to the width of the first electrode 210. The sidewall of the capping film 250 may be disposed on the same plane with the second surface 210S2 of the first electrode. Specifically, the width of the first surface 210S1 of the first electrode in contact with the capping film 250 may be the same as or substantially similar to the width of the capping film 250. Since the capping film 250 and the first electrode 210 are surrounded by the dielectric film 220 in the second direction D2, the widths of the capping film 250 and the first electrode 210 may be identical.

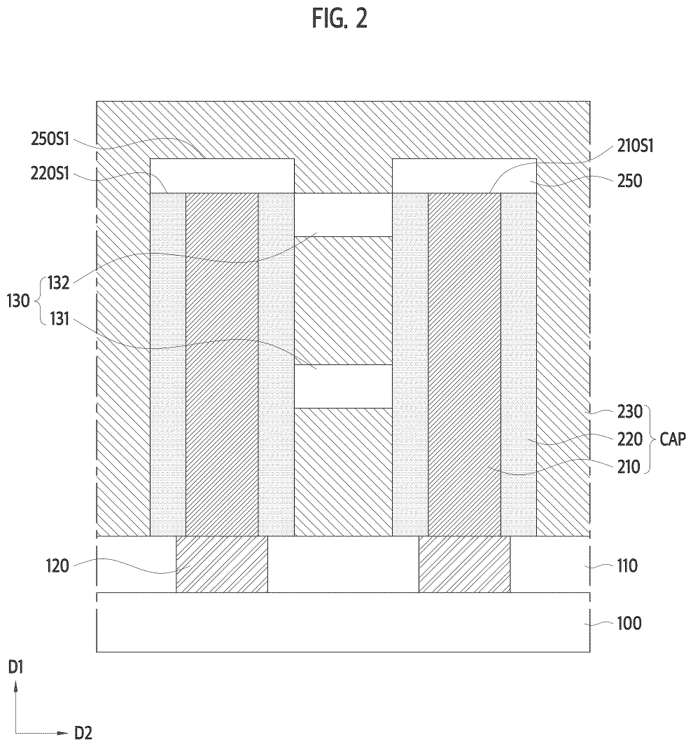

FIG. 2 is an example diagram for illustrating a semiconductor device according to some other example embodiments. To describe the semiconductor device according to some other example embodiments, repeat descriptions with reference to FIG. 1 may be omitted; and a difference from the description with reference to FIG. 1 is mainly described.

Referring to FIG. 2, the capping film 250 may overlap with the dielectric film 220 in the first direction D1. The capping film 250 may cover the first electrode 210 and the dielectric film 220. The capping film 250 may cover both the first surface 210S1 of the first electrode and the first surface 220S1 of the dielectric film. The first surface 250S1 of the capping film may be disposed to not be on the same plane with the first surface 210S1 of the first electrode and the first surface 220S1 of the dielectric film. The first surface 250S1 of the capping film may be disposed to be spaced further apart from the first electrode 210 in the first direction D1 than the first surface 210S1 of the first electrode and the first surface 220S1 of the dielectric film.

According to some example embodiments, based on a horizontal direction (e.g. the second direction D2), the width of the capping film 250 may be greater than the width of the first electrode 210. The sidewall of the capping film 250 may be disposed on the same plane with an outer side surface of the dielectric film 220. The width of the first surface 210S1 of the first electrode in a portion in contact with the capping film 250 may be less than a width of the first surface 250S1 of the capping film. Therefore, since the first electrode 210 is surrounded by the dielectric film 220 in the second direction D2 and the capping film 250 covers both the first electrode 210 and the dielectric film 220, the width of the capping film 250 may be greater than the width of the first electrode 210.

According to some example embodiments, the first surface 210S1 of the first electrode and the first surface 220S1 of the dielectric film may be disposed on the same plane. According to some example embodiments, an extension length of the first electrode 210 and an extension length of the dielectric film 220 may be identical in the first direction D1.

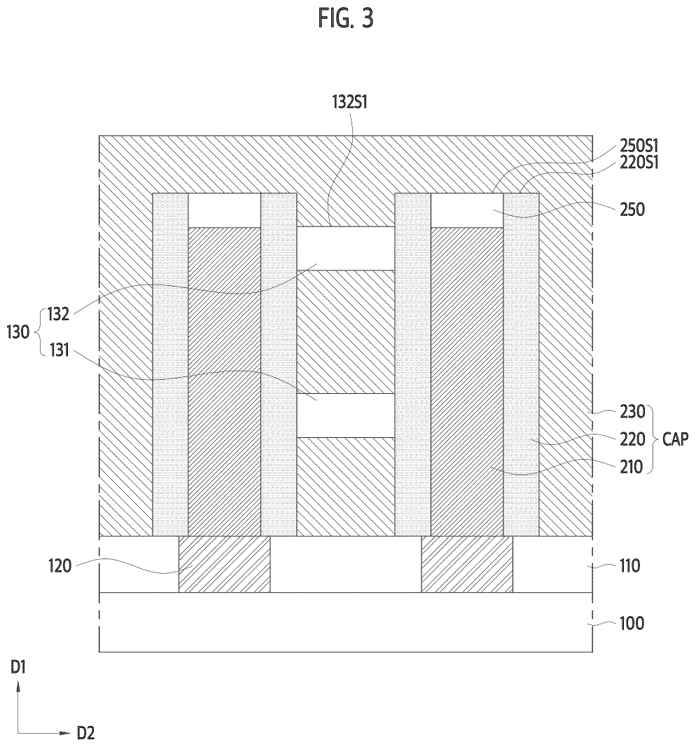

FIG. 3 is an example diagram for illustrating a semiconductor device according to still other example embodiments. To describe the semiconductor device according to still other example embodiments, repeat descriptions with reference to FIG. 1 may be omitted; and a difference from the description with reference to FIG. 1 is mainly described.

Referring to FIG. 3, in the first direction D1, the second supporter 132 may be disposed adjacent to the interlayer insulating film 110 compared to the capping film 250. The upper surface of the first surface 132S1 of the second supporter may be disposed more adjacent to the interlayer insulating film 110 than the first surface 250S1 of the capping film. Between the first surface 250S1 of the capping film and the first surface 220S1 of the dielectric film and the first surface 132S1 of the second supporter, a step may be present.

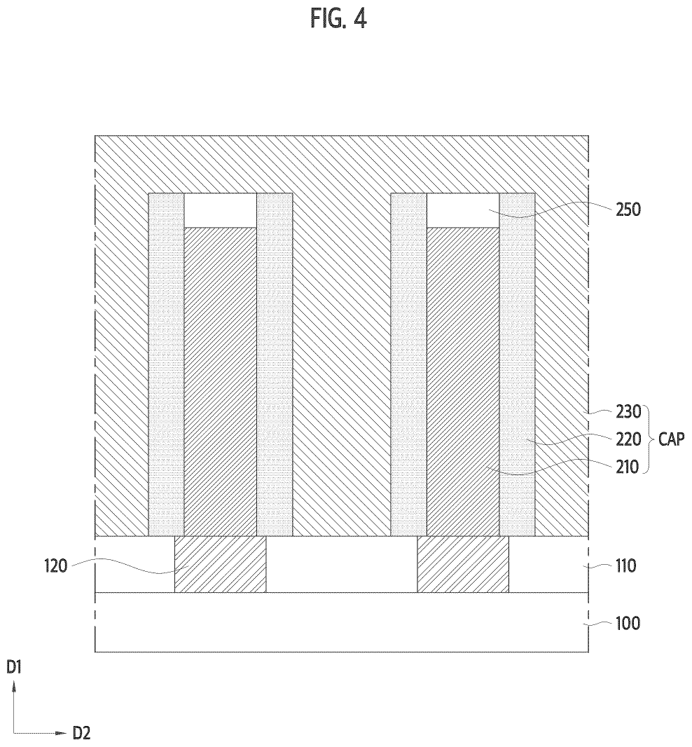

FIG. 4 is an example diagram for illustrating a semiconductor device according to yet other example embodiments. To describe the semiconductor device according to yet other example embodiments, repeat descriptions with reference to FIG. 1 may be omitted; and a difference from the description with reference to FIG. 1 is mainly described.

Referring to FIG. 4, the semiconductor device according to some example embodiments may not include the supporter structure 130 of FIG. 1. The dielectric film 220 may not be connected to the supporter structure 130 of FIG. 1. The entire outer side surface of the dielectric film 220 may be covered by the second electrode 230. The second electrode 230 may fill a space between the dielectric films 220 surrounding the first electrodes 210 adjacent in the second direction D2.

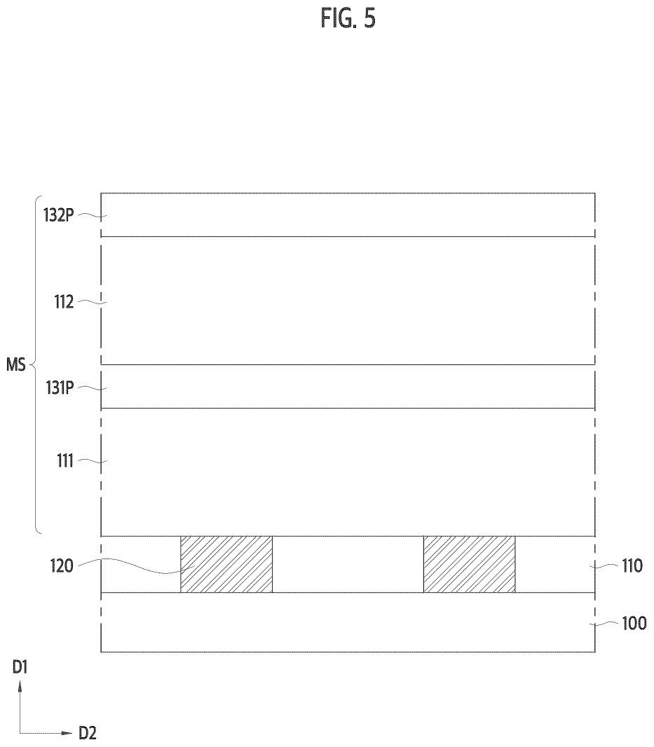

FIGS. 5 to 11 are example diagrams showing intermediate stages for illustrating a method of fabricating a semiconductor device according to some example embodiments. For reference, FIGS. 5 to 11 are diagrams of intermediate stages showing a method of fabricating the semiconductor device illustrated in FIG. 1.

Referring to FIG. 5, a mold structure MS may be formed above the substrate 100 and the interlayer insulating film 110 and the electrode connection structure 120. The mold structure MS may include a first mold film 111, a first pre-supporter 131P, a second mold film 112, and a second pre-supporter 132P. The first mold film 111, the first pre-supporter 131P, the second mold film 112, and the second pre-supporter 132P may be stacked sequentially on the substrate 100.

According to some example embodiments, the first mold film 111 and the second mold film 112 may include silicon oxide, and the first pre-supporter 131P and the second pre-supporter 132P may include silicon nitride. However, example embodiments are not limited thereto. Materials included in the first mold film 111, the first pre-supporter 131P, the second mold film 112, and the second pre-supporter 132P may be changed according to some example embodiments.

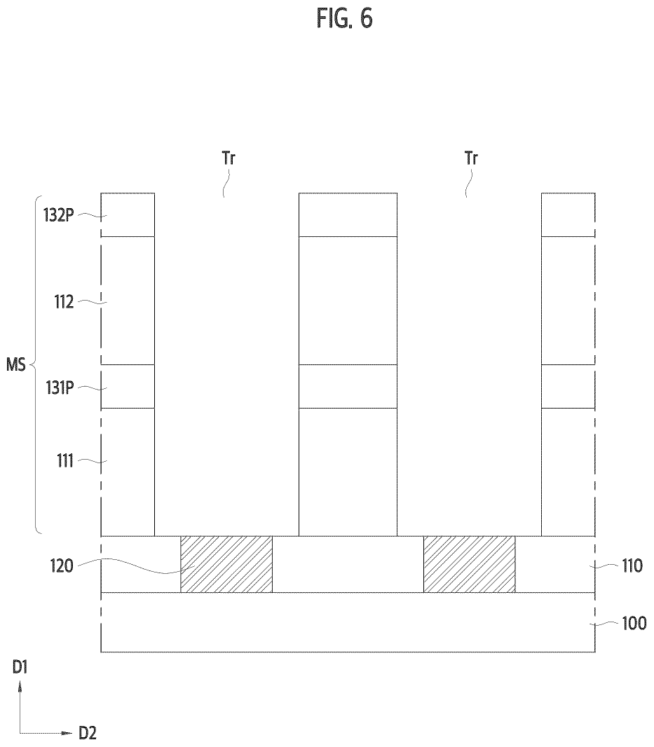

Referring to FIG. 6, a trench Tr penetrating the mold structure MS may be formed. The trench Tr may penetrate the mold structure MS in the vertical direction (e.g. the first direction D1) and expose the electrode connection structure 120. According to some example embodiments, the trench Tr may be formed through a dry etching process. The first pre-supporter 131P and the second pre-supporter 132P may be exposed within the trench Tr.

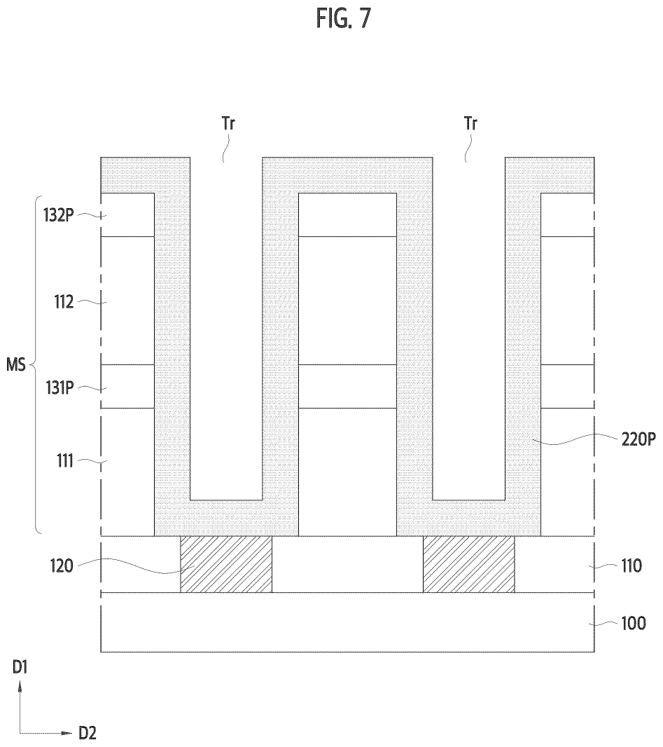

Referring to FIG. 7, a pre-dielectric film 220P may be formed on the trench Tr and the mold structure MS. The pre-dielectric film 220P may extend along profiles of the trench Tr and the mold structure MS. The pre-dielectric film 220P may be formed to cover a bottom surface of the trench Tr and to cover the electrode connection structure 120.

According to some example embodiments, the pre-dielectric film 220P may include a material having an etch selectivity to the first mold film 111 and the second mold film 112 of the mold structure MS. For example, the first mold film 111 and the second mold film 112 may include silicon oxide, and the pre-dielectric film 220P may include nitride including a ferroelectric material.

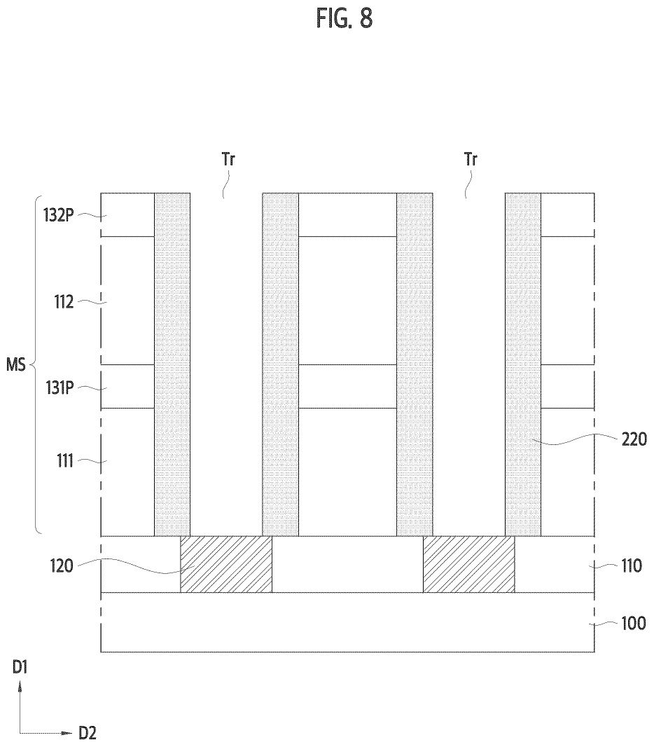

Referring to FIG. 8, as the pre-dielectric film 220P of FIG. 7 on the mold structure MS and the pre-dielectric film 220P on the bottom surface of the trench Tr are removed, the electrode connection structure 120 may be exposed within the trench Tr and the dielectric film 220 may be formed only on a sidewall of the trench Tr. The first pre-supporter 131P and the second pre-supporter 132P exposed within the trench Tr may be in contact with the dielectric film 220. The dielectric film 220 may cover the first pre-supporter 131P and the second pre-supporter 132P exposed within the trench Tr.

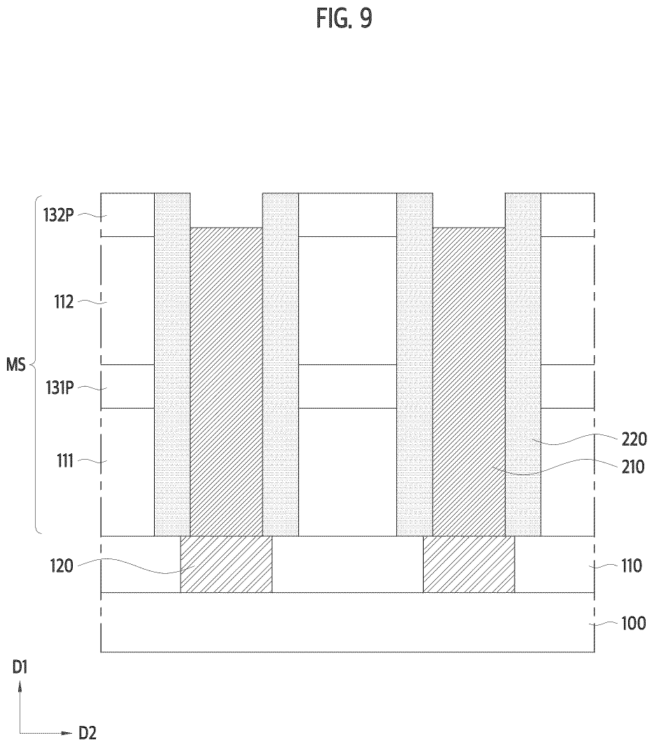

Referring to FIG. 9, the first electrode 210 may be formed on the dielectric film 220 within the trench Tr of FIG. 8. The first electrode 210 may be surrounded by the dielectric film 220 within the trench Tr of FIG. 8. The first electrode 210 may be formed to have a smaller height than the dielectric film 220 in the first direction D1 within the trench Tr of FIG. 8.

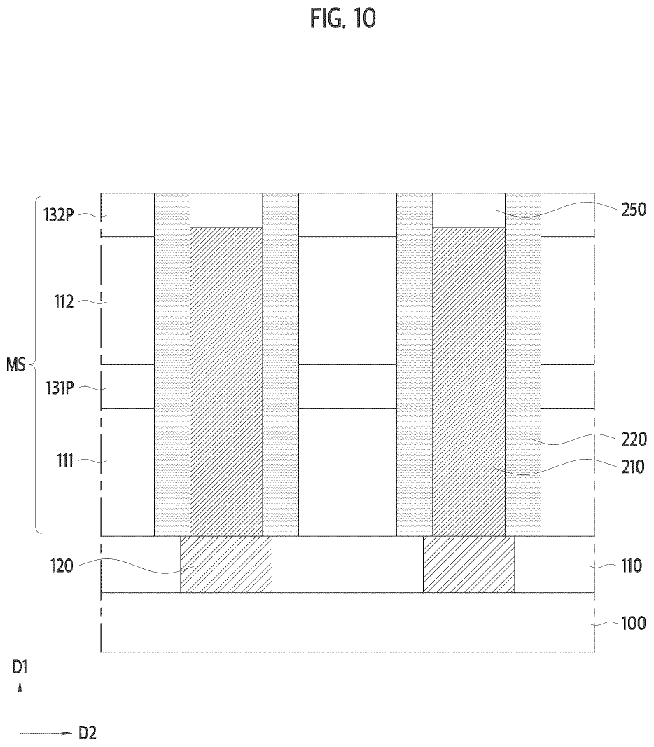

Referring to FIG. 10, the capping film 250 may be formed on the first electrode 210. The capping film 250 may fill the trench Tr of FIG. 8 on the first electrode 210. The capping film 250 may be surrounded by the dielectric film 220 on the first electrode 210.

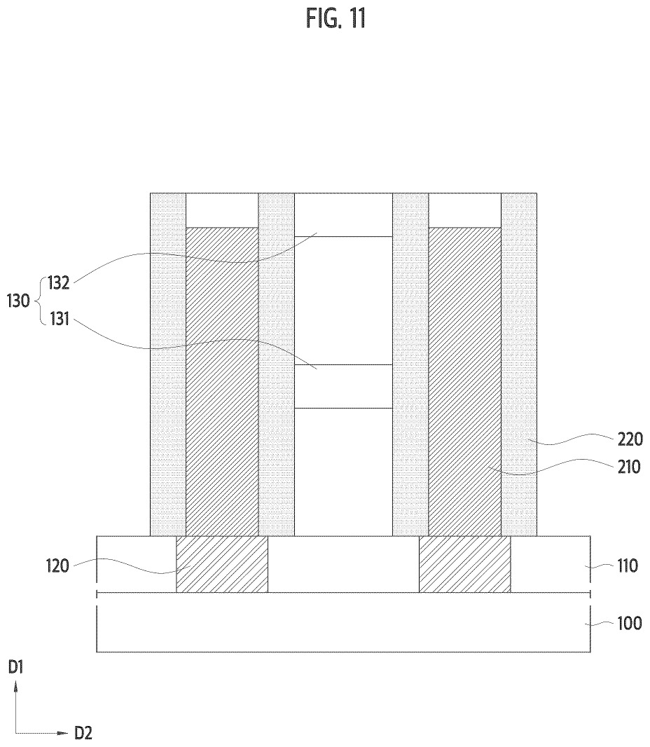

Referring to FIG. 11, the first mold film 111 of FIG. 10 and the second mold film 112 of FIG. 10 among the mold structure MS of FIG. 10 may be removed, and the first supporter 131 and the second supporter 132 may be patterned. As a portion of the first pre-supporter 131P of FIG. 10 and the second pre-supporter 132P of FIG. 10 is removed, the first supporter 131 and the second supporter 132 may be formed.

Subsequently, referring to FIG. 1, the second electrode 230 covering the capping film 250 and the dielectric film 220 may be formed on the substrate 100. The second electrode 230 may fill the space between the first supporter 131 and the second supporter 132.

The method of fabricating the semiconductor device according to some example embodiments may include forming a width of the trench Tr to be relatively large and forming the first electrode 210 after forming the dielectric film 220 within the trench Tr. Since the width of the trench Tr is formed to be relatively large, the trench Tr may penetrate the mold structure MS in a stable manner and the probability of defects in forming the capacitor structure CAP may decrease. Therefore, the difficulty of a fabricating process of the capacitor structure CAP may be decreased and the fabricating process improved. In addition, by forming the first electrode 210 after forming the dielectric film 220 and removing the mold structure MS, the heights of the dielectric film 220 and the first electrode 210 may increase in a stable manner, and thus, the capacitance of the capacitor structure CAP may be enhanced.

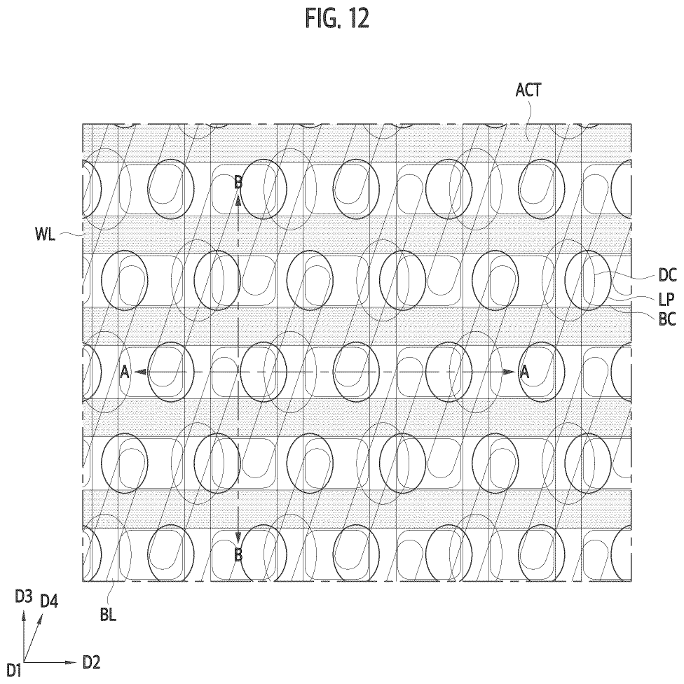

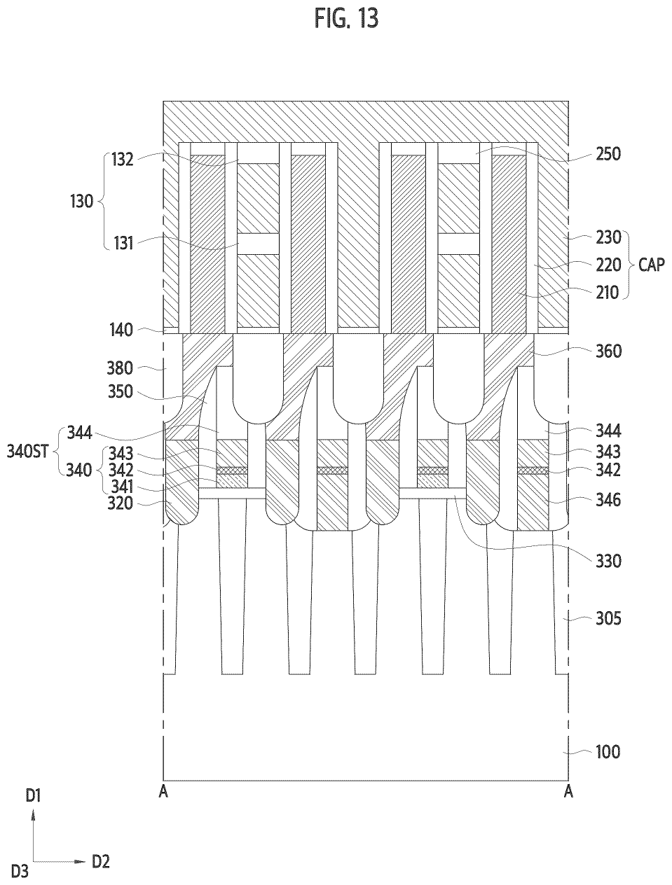

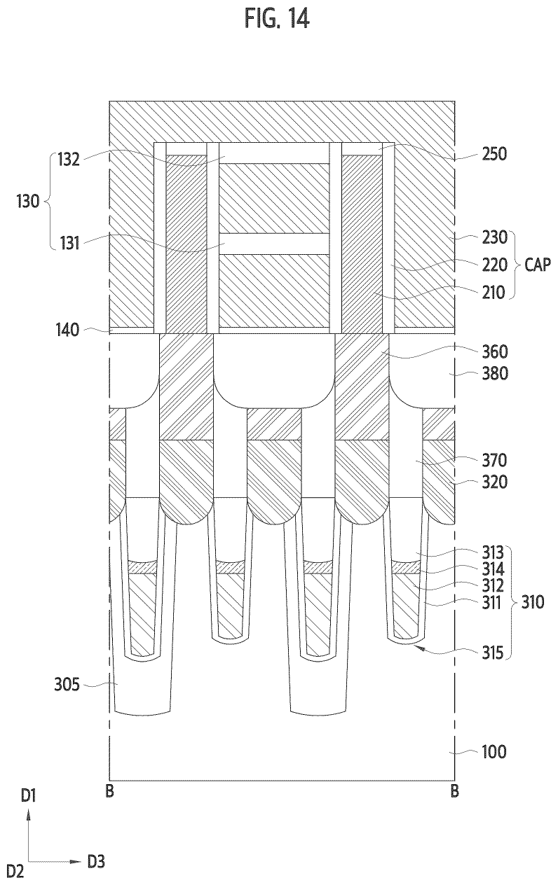

FIG. 12 is a schematic layout diagram for illustrating a semiconductor device according to some example embodiments. FIG. 13 is an example diagram showing a cross-section taken along line A-A of FIG. 12. FIG. 14 is an example diagram showing a cross-section taken along line B-B of FIG. 12. For reference, FIG. 12 illustrates an example layout diagram of dynamic random access memory (DRAM) excluding the capacitor structure CAP, but example embodiments are not limited thereto.

Referring to FIG. 12, the semiconductor device according to some example embodiments may include a plurality of active regions ACT. The active regions ACT may be defined by an element isolation film 305 of FIG. 13 formed within the substrate 100 of FIG. 13.

According to some example embodiments, as dimension of design rules of a semiconductor device are reduced, the active regions ACT may be disposed in a bar shape along a diagonal line or oblique line as illustrated. The active regions ACT may have the form of a bar extending in a fourth direction D4.

According to some example embodiments, on the active regions ACT, a plurality of gate electrodes extending in a horizontal direction (e.g. the second direction D2) across the active regions ACT may be disposed. The plurality of gate electrodes may extend to be parallel to each other. The plurality of gate electrodes may be, for example, a plurality of word lines WL. The word lines WL may be disposed at regular intervals. The width of the word lines WL or intervals between the word lines WL may be determined based on a design rule.

According to some example embodiments, a plurality of bit lines BL extending in a horizontal direction (e.g. the third direction D3) orthogonal to the word lines WL may be disposed on the word lines WL. The plurality of bit lines BL may extend to be parallel to each other.

According to some example embodiments, the bit lines BL may be disposed at regular intervals. The width of the bit lines BL or intervals between the bit lines BL may be determined based on a design rule.

The semiconductor device according to some example embodiments may include various contact arrays formed on the active regions ACT. For example, various contact arrays may include a direct contact DC, a buried contact BC, and a landing pad LP.

According to some example embodiments, the direct contact DC may refer to a contact electrically connecting the active regions ACT to the bit lines BL. The buried contact BC may refer to a contact connecting the active regions ACT to the first electrode 210 of FIG. 13 of the capacitor structure CAP of FIG. 13.

According to some example embodiments, a contact area between the buried contact BC and the active regions ACT may be small based on an arrangement structure. Accordingly, in order to not only increase the contact area with the active regions ACT but also increase a contact area with the first electrode 210 of FIG. 13 of the capacitor structure CAP of FIG. 13, the landing pad LP that is conductive may be introduced.

According to some example embodiments, the landing pad LP may be disposed between the active regions ACT and the buried contact BC and may also be disposed between the buried contact BC and the first electrode 210 of FIG. 13 of the capacitor structure CAP of FIG. 13. By increasing the contact area through the introduction of the landing pad LP, contact resistance between the active regions ACT and the first electrode 210 of FIG. 13 of the capacitor structure CAP of FIG. 13 may decrease.

In the semiconductor device according to some example embodiments, the direct contact DC may be disposed at a central portion of the active regions ACT. The buried contact BC may be disposed at an opposite end portion of the active regions ACT.

According to some example embodiments, as the buried contact BC is disposed at the opposite end portion of the active regions ACT, the landing pad LP may be disposed to be adjacent to an opposite end of the active regions ACT and to partially overlap with the buried contact BC. The buried contact BC may be formed to overlap with the active regions ACT and the element isolation film 305 of FIG. 13 which are present between adjacent word lines WL and between adjacent bit lines BL.

According to some example embodiments, the word lines WL may be formed with a buried structure within the substrate 100. The word lines WL may be disposed across the active regions ACT between the direct contacts DC or the buried contacts BC. As illustrated in FIG. 12, two word lines WL may be disposed to cross one active region ACT. As the active regions ACT are disposed in the form of a diagonal line or oblique line, the word lines WL may have an angle of less than 90 degrees with the active regions ACT.

According to some example embodiments, the direct contact DC and the buried contact BC may be disposed symmetrically. Due to this, the direct contact DC and the buried contact BC may be disposed on a straight line along the second direction D2 and the third direction D3.

According to some example embodiments, unlike the direct contact DC and the buried contact BC, the landing pad LP may be disposed in a zigzag pattern in the third direction D3 where the bit lines BL extend. In addition, the landing pad LP may be disposed to overlap with an identical side portion of each of the bit lines BL in the second direction D2 where the word lines WL extend. For example, each landing pad LP of a first line may overlap with a left side of a corresponding bit line BL, and each landing pad LP of a second line may overlap with a right side of a corresponding bit line BL.

Referring to FIGS. 12 to 14, the semiconductor device according to some example embodiments may include a gate structure 310, a plurality of bit line structures 340ST, a storage contact 320, and the capacitor structure CAP.

According to some example embodiments, the element isolation film 305 may be formed within the substrate 100. The element isolation film 305 may have a shallow trench isolation (STI) structure with a superior element isolation characteristic. The element isolation film 305 may define the active regions ACT on the substrate 100.

According to some example embodiments, the active regions ACT defined by the element isolation film 305 may have a long island shape including a minor axis and a major axis as illustrated in FIG. 12. The active regions ACT may have the form of a diagonal line or oblique line to have an angle of less than 90 degrees with the word lines WL formed within the element isolation film 305.

According to some example embodiments, the element isolation film 305 may include, for example, at least one of a silicon oxide film, a silicon nitride film, and a silicon oxynitride film but is not limited thereto. It is illustrated that the element isolation film 305 is formed as each one insulating film, merely for convenience of description, and example embodiments are not limited thereto. Depending on the width of the element isolation film 305, the element isolation film 305 may be formed as each one insulating film and may also be formed as a plurality of insulating films.

According to some example embodiments, the active regions ACT may have the form of a diagonal line or oblique line to have an angle of less than 90 degrees with the bit lines BL formed on the element isolation film 305. In other words, the active regions ACT may extend in the fourth direction D4 having a predetermined degree with the second direction D2 and the third direction D3.

According to some example embodiments, the gate structure 310 may be formed within the substrate 100 and the element isolation film 305. The gate structure 310 may be formed across the element isolation film 305 and the active regions ACT defined by the element isolation film 305. The gate structure 310 may include a gate trench 315, a gate insulating film 311, a gate electrode 312, a gate capping pattern 313, and a gate capping conductive film 314 which are formed within the substrate 100 and the element isolation film 305. Here, the gate electrode 312 may correspond to the word lines WL. Unlike what is illustrated, according to at least some example embodiments, the gate structure 310 may not include the gate capping conductive film 314.

According to some example embodiments, the gate insulating film 311 may extend along a sidewall and a bottom surface of the gate trench 315. The gate insulating film 311 may extend along a profile of at least a portion of the gate trench 315. For example, the gate insulating film 311 may include an insulating material, such as at least one of silicon oxide, silicon nitride, silicon oxynitride, a high-permittivity material with a higher dielectric constant than silicon oxide, and/or the like. The high-permittivity material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and/or a combination thereof.

According to some example embodiments, the gate electrode 312 may be formed on the gate insulating film 311. The gate electrode 312 may fill a portion of the gate trench 315. The gate capping conductive film 314 may extend along an upper surface of the gate electrode 312.

According to some example embodiments, the gate electrode 312 may include a conductive material, such as at least one of metal, metal alloy, conductive metal nitride, conductive metal carbonitride, conductive metal carbide, metal silicide, doped semiconductor material, conductive metal oxynitride, conductive metal oxide, and/or the like. For example, the gate electrode 312 may include, but is not limited to, at least one of TiN, TaC, TaN, TiSiN, TaSiN, TaTiN, TiAlN, TaAlN, WN, Ru, TiAl, TiAlC-N, TiAlC, TiC, TaCN, W, Al, Cu, Co, Ti, Ta, Ni, Pt, Ni-Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx, and/or a combination thereof. The gate capping conductive film 314 may include, for example, polysilicon or polysilicon germanium but is not limited thereto.

According to some example embodiments, the gate capping pattern 313 may be disposed on the gate electrode 312 and the gate capping conductive film 314. The gate capping pattern 313 may fill the gate trench 315 which remains after the gate electrode 312 and the gate capping conductive film 314 are formed. It is illustrated that the gate insulating film 311 extends along a sidewall of the gate capping pattern 313, but example embodiments are not limited thereto. The gate capping pattern 313 may include, for example, at least one of silicon nitride (SiN), silicon oxynitride (SiON), silicon oxide (SiO2), silicon carbonitride (SiCN), silicon oxycarbonitride (SiOCN), and/or a combination thereof.

According to some example embodiments, an impurity-doped region may be formed in at least one side of the gate structure 310. The impurity-doped region may be a source/drain region of a transistor.

According to some example embodiments, the bit line structures 340ST may include a cell conductive line 340 and a cell line capping film 344. The cell conductive line 340 may be formed on the substrate 100 and the element isolation film 305 where the gate structure 310 is formed. The cell conductive line 340 may intersect with the element isolation film 305 and the active regions ACT. The cell conductive line 340 may be formed to intersect with the gate structure 310. Here, the cell conductive line 340 may correspond to the bit lines BL.

According to some example embodiments, the cell conductive line 340 may be a multilayer. The cell conductive line 340 may include, for example, a first cell conductive film 341, a second cell conductive film 342, and a third cell conductive film 343. The first to third cell conductive films 341, 342, and 343 may be stacked sequentially on the substrate 100 and the element isolation film 305. The cell conductive line 340 is illustrated as a triple layer but is not limited thereto.

According to some example embodiments, each of the first to third cell conductive films 341, 342, and 343 may include a conductive material, for example, at least one of impurity-doped semiconductor material, conductive silicide compound, conductive metal nitride, metal, metal alloy, and/or the like. For example, the first cell conductive film 341 may include a doped semiconductor material, the second cell conductive film 342 may include at least one of conductive silicide compound and/or a conductive metal nitride, and the third cell conductive film 343 may include at least one of metal and metal alloy, but example embodiments are not limited thereto.

According to some example embodiments, a bit line contact 346 may be formed between the cell conductive line 340 and the substrate 100. In other words, the cell conductive line 340 may be formed on the bit line contact 346. For example, the bit line contact 346 may be formed at a point where the cell conductive line 340 intersects with a middle portion of the active regions ACT having a long island shape.

According to some example embodiments, the bit line contact 346 may electrically connect the cell conductive line 340 and the substrate 100. Here, the bit line contact 346 may correspond to the direct contact DC. The bit line contact 346 may include, for example, at least one of impurity-doped semiconductor material, conductive silicide compound, conductive metal nitride, and metal.

According to some example embodiments, in FIG. 13, the cell conductive line 340, at a region overlapping with an upper surface of the bit line contact 346, may include the second cell conductive film 342 and the third cell conductive film 343. At a region non-overlapping with the upper surface of the bit line contact 346, the cell conductive line 340 may include the first to third cell conductive films 341, 342, and 343.

According to some example embodiments, the cell line capping film 344 may be disposed on the cell conductive line 340. The cell line capping film 344 may extend in the third direction D3 along an upper surface of the cell conductive line 340. In these cases, the cell line capping film 344 may include, for example, at least one of silicon nitride, silicon oxynitride, silicon carbonitride, silicon oxycarbonitride, and/or the like. In the semiconductor device according to some example embodiments, the cell line capping film 344 may include, for example, a silicon nitride film. The cell line capping film 344 is illustrated as a single layer but is not limited thereto. The cell line capping film 344 may also be a multilayer. However, when each film composing the multilayer is an identical material, the cell line capping film 344 may also be shown as the single layer.

According to some example embodiments, a cell insulating film 330 may be formed on the substrate 100 and the element isolation film 305. More specifically, the cell insulating film 330 may be formed on the substrate 100 and the element isolation film 305, where the bit line contact 346 is not formed. The cell insulating film 330 may be formed between the substrate 100 and the cell conductive line 340 and between the element isolation film 305 and the cell conductive line 340.

According to some example embodiments, the cell insulating film 330 may be a single layer as illustrated, but example embodiments are not limited thereto. For example, the cell insulating film 330 may also be a multilayer. For example, the cell insulating film 330 may include a first insulating film including a silicon oxide film and a second insulating film including a silicon nitride film.

According to some example embodiments, a cell line spacer 350 may be disposed on a sidewall of the cell conductive line 340 and a sidewall of the cell line capping film 344. The cell line spacer 350 may be formed on the substrate 100 and the element isolation film 305 at a portion of the cell conductive line 340 where the bit line contact 346 is formed. The cell line spacer 350 may be disposed on the sidewall of the cell conductive line 340, the sidewall of the cell line capping film 344, and a sidewall of the bit line contact 346.

According to some example embodiments, at a remaining portion of the cell conductive line 340 where the bit line contact 346 is not formed, the cell line spacer 350 may be disposed on the cell insulating film 330. The cell line spacer 350 may be disposed on the sidewall of the cell conductive line 340 and the sidewall of the cell line capping film 344.

According to some example embodiments, the cell line spacer 350 may be a single layer as illustrated, but example embodiments are not limited thereto. For example, the cell line spacer 350 may also be a multilayer. The cell line spacer 350 may include a multilayer each including one of a silicon oxide film, a silicon nitride film, a silicon oxynitride film (SiON), a silicon oxycarbonitride film (SiOCN), air, and a combination thereof.

According to some example embodiments, a fence pattern 370 may be disposed on the substrate 100 and the element isolation film 305. The fence pattern 370 may be formed to overlap with the gate structure 310 formed within the substrate 100 and the element isolation film 305. The fence pattern 370 may be disposed between the bit line structures 340ST extending in the third direction D3. For example, the fence pattern 370 may include at least one of silicon oxide, silicon nitride, silicon oxynitride, and a combination thereof.

According to some example embodiments, the storage contact 320 may be disposed between the bit lines BL adjacent in the second direction D2. Specifically, the storage contact 320 may be disposed between the cell conductive lines 340 adjacent in the second direction D2. The storage contact 320 may be disposed between the fence patterns 370 adjacent in the third direction D3. The storage contact 320 may overlap with the substrate 100 and the element isolation film 305 between the adjacent cell conductive lines 340. The storage contact 320 may be connected to the active regions ACT. Here, the storage contact 320 may correspond to the buried contact BC.

According to some example embodiments, the storage contact 320 may include at least one of impurity-doped semiconductor material, conductive silicide compound, conductive metal nitride, and metal.

According to some example embodiments, a storage pad 360 may be formed on the storage contact 320. The storage pad 360 may be electrically connected to the storage contact 320. The storage pad 360 may be connected to a cell active region. The storage pad 360 may correspond to the landing pad LP. In addition, the storage pad 360 may correspond to the electrode connection structure 120 of FIGS. 1 to 4.

According to some example embodiments, the storage pad 360 may overlap with a portion of an upper surface of the bit line structures 340ST. The storage pad 360 may include, for example, at least one of impurity-doped semiconductor material, conductive silicide compound, conductive metal nitride, conductive metal carbide, metal, and metal alloy.

According to some example embodiments, a pad isolation insulating film 380 may be formed on the storage pad 360 and the bit line structures 340ST. For example, the pad isolation insulating film 380 may be disposed on the cell line capping film 344. The pad isolation insulating film 380 may define the storage pad 360 which forms a plurality of isolated regions. The pad isolation insulating film 380 may not cover an upper surface of the storage pad 360. For example, based on an upper surface of the substrate 100, a height of the upper surface of the storage pad 360 may be identical to a height of an upper surface of the pad isolation insulating film 380.

According to some example embodiments, the pad isolation insulating film 380 may include an insulating material and may electrically isolate a plurality of storage pads 360 from each other. For example, the pad isolation insulating film 380 may include at least one of a silicon oxide film, a silicon nitride film, a silicon oxynitride film, a silicon oxycarbonitride film, and a silicon carbonitride film. According to some example embodiments the pad isolation insulating film 380 and the storage pad 360 corresponds to the interlayer insulating film 110 and the electrode connection structure 120, respectively.

According to some example embodiments, an etch stop film 140 may be disposed on the upper surface of the storage pad 360 and the upper surface of the pad isolation insulating film 380. For example, the etch stop film 140 may include at least one of silicon nitride (SiN), silicon carbonitride (SiCN), silicon oxycarbonitride (SiOCN), silicon oxycarbide (SiOC), and silicon boron nitride (SiBN).

According to some example embodiments, the capacitor structure CAP may be disposed on the storage pad 360. The capacitor structure CAP may be connected to the storage pad 360. Therefore, the capacitor structure CAP may be electrically connected to the storage contact 320 through the storage pad 360.

According to some example embodiments, the capacitor structure CAP may include the first electrode 210, the dielectric film 220, and the second electrode 230. The first supporter 131 and the second supporter 132 may be disposed on the etch stop film 140.

According to some example embodiments, descriptions of the first electrode 210, the dielectric film 220, and the second electrode 230 included in the capacitor structure CAP may be substantially identical to the description with reference to FIGS. 1 to 4.

According to some example embodiments, the first electrode 210 may be surrounded by the dielectric film 220 and the capping film 250. The first electrode 210 may not be in contact with and may be spaced apart from the supporter structure 130 with the dielectric film 220 in between. The second electrode 230 may be in contact with the supporter structure 130 and may fill the space between the first supporter 131 and the second supporter 132. The dielectric film 220 may be disposed as to not overlap with the supporter structure 130 in the first direction D1 and may extend in the first direction D1 along the first electrode 210. In addition, the capping film 250 may overlap with the first electrode 210 in the first direction D1 and be disposed between the first electrode 210 and the second electrode 230.

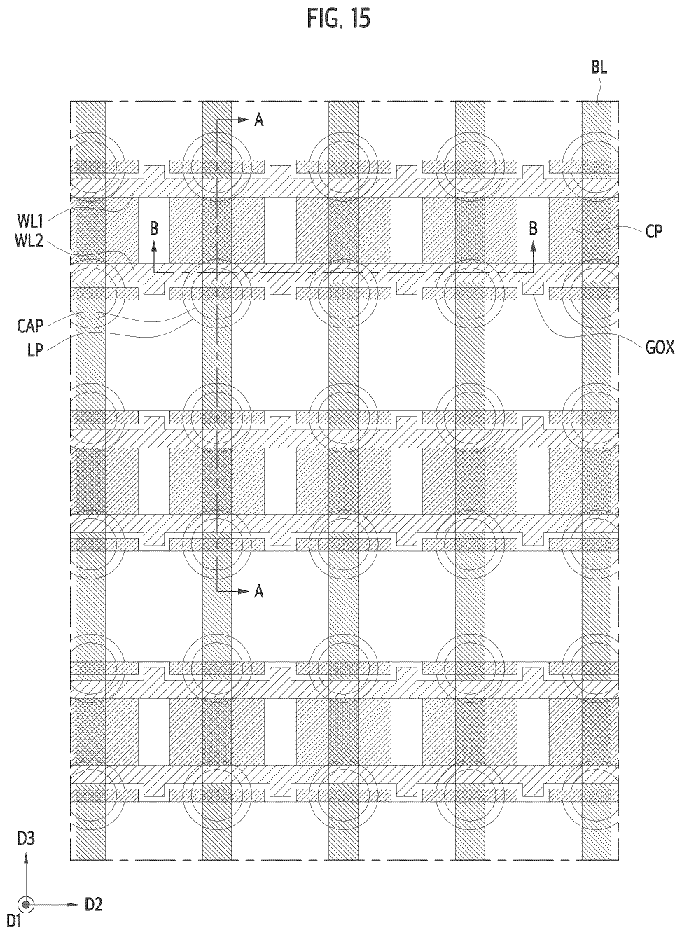

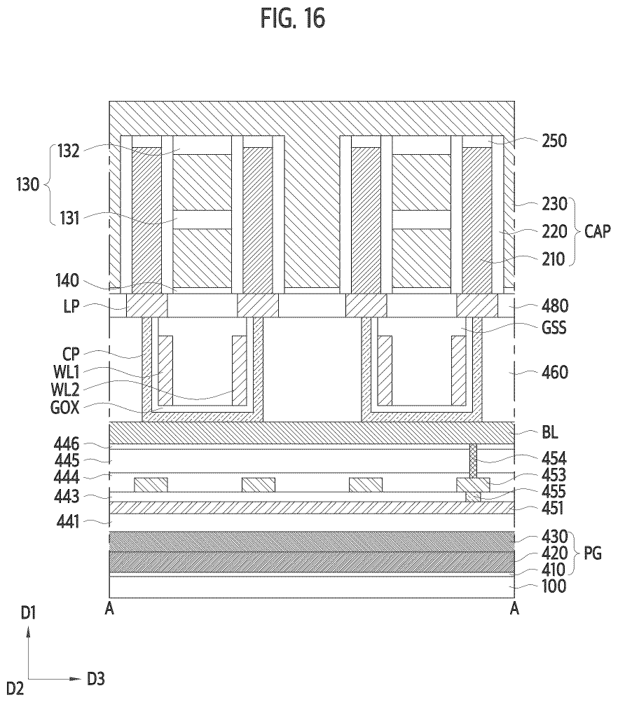

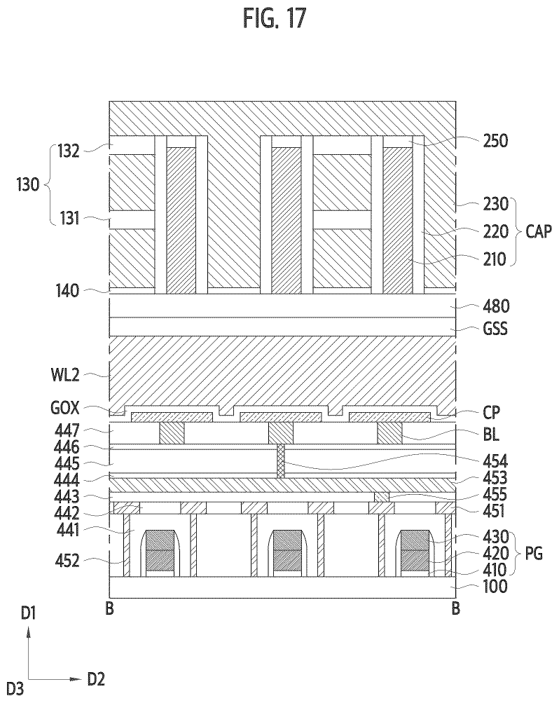

FIG. 15 is a schematic layout diagram for illustrating a semiconductor device according to some other example embodiments. FIG. 16 is an example diagram showing a cross-section taken along line A-A of FIG. 15. FIG. 17 is an example diagram showing a cross-section taken along line B-B of FIG. 15. For reference, FIG. 15 illustrates an example layout diagram of dynamic random access memory (DRAM) including a vertical channel transistor (VCT), but example embodiments are not limited thereto.

Referring to FIGS. 15 to 17, the semiconductor device according to some example embodiments may include a peripheral gate structure PG, a channel pattern CP, a first word line WL1, a second word line WL2, the bit lines BL, and the capacitor structure CAP.

According to some example embodiments, the substrate 100 may be a silicon substrate or may include, but is not limited to, other materials such as silicon germanium, indium antimonide, lead telluride, indium arsenide, indium phosphide, gallium arsenide, or gallium antimonide.

According to some example embodiments, the peripheral gate structure PG may be disposed on the substrate 100. The substrate 100 may include a cell array region and a peripheral circuit region. The peripheral gate structure PG may be disposed over the cell array region and the peripheral circuit region. In other words, a portion of the peripheral gate structure PG may be disposed on the cell array region of the substrate 100, and a remaining portion of the peripheral gate structure PG may be disposed on the peripheral circuit region of the substrate 100.

According to some example embodiments, the peripheral gate structure PG may be included in a sensing transistor, a transmission transistor, and a driver transistor. The type of a transistor disposed on the cell array region and the peripheral circuit region may also vary depending on a design arrangement of a semiconductor device.

According to some example embodiments, the peripheral gate structure PG may include a peripheral gate insulating film 410, a peripheral lower conductive pattern 420, and a peripheral upper conductive pattern 430.

According to some example embodiments, the peripheral gate insulating film 410 may include an insulating film, such as at least one of a silicon oxide film, a silicon oxynitride film, a high-permittivity insulating film with a higher dielectric constant than a silicon oxide film, and/or a combination thereof. For example, the high-permittivity insulating film may include, but is not limited to, at least one of metal oxide, metal oxynitride, metal silicon oxide, and metal silicon oxynitride.

According to some example embodiments, each of the peripheral lower conductive pattern 420 and the peripheral upper conductive pattern 430 may include a conductive material. For example, each of the peripheral lower conductive pattern 420 and the peripheral upper conductive pattern 430 may include at least one of doped semiconductor material, conductive metal nitride, conductive metal silicon nitride, metal carbonitride, conductive metal silicide, conductive metal oxide, two-dimensional (2D) material, metal, and metal alloy. The peripheral gate structure PG is illustrated as including a plurality of conductive patterns but is not limited thereto.

In the semiconductor device according to some example embodiments, the 2D material may be a metallic material and/or a semiconductor material. The 2D material may include a 2D allotrope or a 2D compound and may include, for example, at least one of graphene, molybdenum disulfide (MoS2), molybdenum diselenide (MoSe2), tungsten diselenide (WSe2), and tungsten disulfide (WS2) but is not limited thereto. According to some example embodiments, the 2D semiconductor material may include an impurity (and/or dopant) selected to increase the conductivity of the 2D material.

According to some example embodiments, a first peripheral insulating film 441 and a second peripheral insulating film 442 may be disposed on the substrate 100. The first peripheral insulating film 441 and the second peripheral insulating film 442 may include an insulating material.

According to some example embodiments, a first peripheral interconnect line 451 and a peripheral contact plug 452 may be disposed within the first peripheral insulating film 441 and the second peripheral insulating film 442. The first peripheral interconnect line 451 and the peripheral contact plug 452 are illustrated as different layers but are not limited thereto. A boundary between the first peripheral interconnect line 451 and the peripheral contact plug 452 may also not be divided. Each of the first peripheral interconnect line 451 and the peripheral contact plug 452 may include a conductive material.

According to some example embodiments, a third peripheral insulating film 443 and a fourth peripheral insulating film 444 may be disposed on the first peripheral interconnect line 451 and the peripheral contact plug 452. Each of the third peripheral insulating film 443 and the fourth peripheral insulating film 444 may consist of an insulating material.

According to some example embodiments, a second peripheral interconnect line 453 and a peripheral via plug 455 may be disposed on the first peripheral interconnect line 451. The peripheral via plug 455 may be disposed within the third peripheral insulating film 443. The second peripheral interconnect line 453 may be disposed within the fourth peripheral insulating film 444.

According to some example embodiments, the second peripheral interconnect line 453 and the peripheral via plug 455 may be connected to the first peripheral interconnect line 451. The peripheral via plug 455 may connect the first peripheral interconnect line 451 and the second peripheral interconnect line 453. Each of the second peripheral interconnect line 453 and the peripheral via plug 455 may include a conductive material. The second peripheral interconnect line 453 and the peripheral via plug 455 are illustrated as different layers but are not limited thereto. A boundary between the second peripheral interconnect line 453 and the peripheral via plug 455 may not be divided.

According to some example embodiments, the fourth peripheral insulating film 444, a fifth peripheral insulating film 445, and a sixth peripheral insulating film 446 may be disposed sequentially on the third peripheral insulating film 443. Each of the fourth peripheral insulating film 444, the fifth peripheral insulating film 445, and the sixth peripheral insulating film 446 may consist of an insulating material.

According to some example embodiments, the fifth peripheral insulating film 445 may consist of a different insulating material from the fourth peripheral insulating film 444 and the sixth peripheral insulating film 446. For example, the fifth peripheral insulating film 445 may consist of an oxide-based insulating material, and the fourth peripheral insulating film 444 and the sixth peripheral insulating film 446 may consist of a nitride-based insulating material, but example embodiments are not limited thereto.

According to some example embodiments, a cell connection plug 454 may be disposed within the fourth peripheral insulating film 444, the fifth peripheral insulating film 445, and the sixth peripheral insulating film 446. The cell connection plug 454 may be connected to the second peripheral interconnect line 453 and the bit lines BL. The cell connection plug 454 may include a conductive material.

According to some example embodiments, the bit lines BL may be disposed on the peripheral gate structure PG. The bit lines BL may be disposed on the sixth peripheral insulating film 446. The bit lines BL may extend long in the third direction D3. The adjacent bit lines BL may be spaced apart in the second direction D2. The bit lines BL may include a long side wall extending in the third direction D3 and a short side wall extending in the second direction D2.

Although not illustrated, each of the bit lines BL may extend from the cell array region to the peripheral circuit region. An end portion of each of the bit lines BL may be disposed on the peripheral circuit region of the substrate 100.

According to some example embodiments, each of the bit lines BL may be disposed on the cell connection plug 454. Each of the bit lines BL may be connected to the cell connection plug 454. Each of the bit lines BL may include a conductive material, for example, at least one of doped semiconductor material, conductive metal nitride, conductive metal silicon nitride, metal carbonitride, conductive metal silicide, conductive metal oxide, 2D material, metal, and metal alloy. Each of the bit lines BL is illustrated as a single layer but is not limited thereto.

According to some example embodiments, a cell lower insulating film 447 may be disposed on the sixth peripheral insulating film 446. The cell lower insulating film 447 may be disposed between the bit lines BL spaced apart in the second direction D2. The cell lower insulating film 447 may include an insulating material.

According to some example embodiments, an insulating pattern 460 may be disposed on the bit lines BL. The insulating pattern 460 may include an insulating material. It is illustrated that a lower surface of the insulating pattern 460 is in direct contact with the bit lines BL, but example embodiments are not limited thereto. For example, an etch stop film may be disposed between the insulating pattern 460 and the bit lines BL. The etch stop film may include a material having an etch selectivity to the insulating pattern 460.

According to some example embodiments, the channel pattern CP may be disposed on each of the bit lines BL. A plurality of channel patterns CP may be connected to one bit line BL. The plurality of channel patterns CP disposed on one bit line BL may be spaced apart in the third direction D3. For example, the channel patterns CP may be arranged two-dimensionally along the second direction D2 and the third direction D3 intersecting with each other.

According to some example embodiments, in a cross-section taken along the third direction D3, the channel pattern CP may have a “U” shape. Specifically, the channel pattern CP may include a horizontal part and a vertical part.

According to some example embodiments, the horizontal part of the channel pattern CP may extend along an upper surface of the bit lines BL and an upper surface of the cell lower insulating film 447. The horizontal part of the channel pattern CP may be disposed below the first and second word lines WL1 and WL2. The horizontal part of the channel pattern CP may be disposed below a gate insulating film GOX.

According to some example embodiments, the vertical part of the channel pattern CP may protrude from the horizontal part in the first direction D1. The vertical part of the channel pattern CP may extend from the horizontal part along the first direction D1. The vertical part of the channel pattern CP may extend along a side surface of the insulating pattern 460. Specifically, in the cross-section taken along the third direction D3, the vertical part of the channel pattern CP may extend along a sidewall of the insulating pattern 460.

According to some example embodiments, the channel pattern CP may include an oxide semiconductor material. The channel pattern CP may include, for example, metal oxide. As an example, the channel pattern CP may be an amorphous metal oxide film. As another example, the channel pattern CP may be a polycrystalline metal oxide film. As yet another example, the channel pattern CP may be a combination of the amorphous metal oxide film and the polycrystalline metal oxide film. As still another example, the channel pattern CP may be a c-axis aligned crystalline (CAAC) metal oxide film.

According to some example embodiments, the channel pattern CP may include, for example, at least one of indium oxide, tin oxide, zinc oxide, In—Zn-based oxide (IZO), Sn—Zn-based oxide, Al—Zn-based oxide, Zn—Mg-based oxide, Sn—Mg-based oxide, In—Mg-based oxide, In—Ga-based oxide (IGO), In—Ga—Zn-based oxide (IGZO), In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, In—Lu—Zn-based oxide, In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, and/or In—Hf—Al—Zn-based oxide but is not limited thereto.

Here, In—Ga—Zn-based oxide may refer to oxide with In and Ga and Zn as main components and may not indicate a ratio of In and Ga and Zn. In other words, as an example using indium gallium zinc oxide (IGZO), the channel pattern CP may include indium gallium zinc oxide or InxGayZnzO (IGZO). IGZO having equal ratios of indium, gallium, and zinc (In:Ga:Zn=1:1:1) may be In—Ga—Zn-based oxide. Ga-rich IGZO may have a higher ratio of gallium than IGZO (In:Ga:Zn=1:1:1) and have a lower ratio of indium than IGZO (In:Ga:Zn=1:1:1). Ga-rich IGZO may also be In—Ga—Zn-based oxide. In addition, In-rich IGZO may have a higher ratio of indium than IGZO (In:Ga:Zn=1:1:1) and have a lower ratio of gallium than IGZO (In:Ga:Zn=1:1:1). In-rich IGZO may also be In—Ga—Zn-based oxide.

The above description uses IGZO, but example embodiments are not limited thereto. When each channel pattern CP includes metal oxide having more than 3 components, the above description may also be applied. In addition, when the channel pattern CP includes In—Ga—Zn-based oxide, the channel pattern CP may further include a doped metal element in addition to In, Ga, and Zn.

According to some example embodiments, the first word line WL1 may include a first sidewall and a second sidewall. The first sidewall of the first word line WL1 may face the sidewall of the insulating pattern 460. The first sidewall of the first word line WL1 may face the second word line WL2 with the insulating pattern 460 in between. The first sidewall of the first word line WL1 may extend along the gate insulating film GOX. The second sidewall of the first word line WL1 may face a gate isolation pattern GSS. The second sidewall of the first word line WL1 may extend along the gate isolation pattern GSS.

According to some example embodiments, the second word line WL2 may include a third sidewall and a fourth sidewall. The third sidewall of the second word line WL2 may face the sidewall of the insulating pattern 460. The third sidewall of the second word line WL2 may face the first word line WL1 with the insulating pattern 460 in between. The third sidewall of the second word line WL2 may extend the gate insulating film GOX. The fourth sidewall of the second word line WL2 may face the gate isolation pattern GSS. The fourth sidewall of the second word line WL2 may extend along the gate isolation pattern GSS.

According to some example embodiments, the first word line WL1 and the second word line WL2 may be disposed on the channel pattern CP.

Each of the first word line WL1 and the second word line WL2 may extend in the first direction D1. The first word line WL1 and the second word line WL2 may be disposed alternately in the third direction D3. The first word line WL1 may be spaced apart from the second word line WL2 in the third direction D3.

According to some example embodiments, the first word line WL1 and the second word line WL2 may be spaced apart from the bit lines BL in the first direction D1. The first word line WL1 and the second word line WL2 may intersect with the bit lines BL.

According to some example embodiments, the first word line WL1 and the second word line WL2 may be disposed on the horizontal part of the channel pattern CP. The first word line WL1 and the second word line WL2 may be disposed between the vertical parts of the channel pattern CP.

According to some example embodiments, an upper surface of the first word line WL1 and an upper surface of the second word line WL2 may be disposed below an upper surface of the channel pattern CP. However, example embodiments are not limited thereto.

According to some example embodiments, the first and second word lines WL1 and WL2 may include a conductive material and may include, for example, at least one of doped polysilicon, conductive metal nitride, conductive metal silicon nitride, metal carbonitride, conductive metal silicide, conductive metal oxide, 2D material, metal, and metal alloy.

According to some example embodiments, the gate insulating film GOX may be disposed between the first word line WL1 and the channel pattern CP and between the second word line WL2 and the channel pattern CP.

According to some example embodiments, the gate insulating film GOX may extend along profiles of the first and second word lines WL1 and WL2 and the channel pattern CP. The gate insulating film GOX may extend along the horizontal part of the channel pattern CP which extends along the upper surface of the bit lines BL. The gate insulating film GOX may extend in the first direction D1 along the vertical part of the channel pattern CP which extends along the side surface of the insulating pattern 460.

According to some example embodiments, the gate insulating film GOX may include a silicon oxide film, a silicon oxynitride film, a high-permittivity insulating film with a higher dielectric constant than a silicon oxide film, or a combination thereof.

According to some example embodiments, a portion of the gate insulating film GOX may protrude further in the first direction D1 than the upper surfaces of the first and second word lines WL1 and WL2. An upper surface of the gate insulating film GOX may be disposed on the same plane with an upper surface of the gate isolation pattern GSS. The upper surface of the gate insulating film GOX may be disposed on the same plane with an upper surface of the insulating pattern 460.

According to some example embodiments, the gate isolation pattern GSS may be disposed on the bit lines BL. The gate isolation pattern GSS may be disposed on the channel pattern CP, the gate insulating film GOX, the first word line WL1, and the second word line WL2.

In the semiconductor device according to some example embodiments, the gate isolation pattern GSS may be in contact with the channel pattern CP. The gate isolation pattern GSS may be spaced apart from the bit lines BL in the third direction D3.

According to some example embodiments, the gate isolation pattern GSS may be disposed between the first word line WL1 and the second word line WL2 which are adjacent in the third direction D3. The first word line WL1 and the second word line WL2 may be isolated by the gate isolation pattern GSS.

According to some example embodiments, the first word line WL1 may be disposed between the gate isolation pattern GSS and the channel pattern CP. The second word line WL2 may be disposed between the gate isolation pattern GSS and the channel pattern CP.

According to some example embodiment, the gate isolation pattern GSS may be a single layer. In the cross-section taken along the third direction D3, the gate isolation pattern GSS may have a “T” shape.

According to some example embodiments, based on the upper surface of the bit lines BL, the upper surface of the gate isolation pattern GSS may be flush with the upper surface of the insulating pattern 460 but is not limited thereto.

According to some example embodiments, the landing pads LP may be disposed on the channel pattern CP. The landing pads LP may be connected to the vertical part of the channel pattern CP. In a top view viewed from the first direction D1, the landing pads LP may have various shapes such as circles, ellipses, rectangles, squares, rhombuses, and hexagons.

According to some example embodiments, the landing pad P may be disposed on the insulating pattern 460 and the gate isolation pattern GSS. The landing pad LP may be in contact with the upper surface of the insulating pattern 460 and the upper surface of the gate isolation pattern GSS. The landing pad LP may be disposed between pad isolation insulating patterns 480.

According to some example embodiments, the pad isolation insulating patterns 480 may be disposed between the landing pads LP. From a planar perspective, the landing pads LP may be arranged in a matrix form along the first direction D1 and the second direction D2. An upper surface of the landing pad LP may be placed on the same plane with an upper surface of the pad isolation insulating patterns 480 but is not limited thereto.

According to some example embodiments, the landing pad LP may be disposed on the channel pattern CP. The landing pad LP may overlap with the channel pattern CP in the first direction D1. The landing pad LP may be connected to the channel pattern CP. The landing pad LP may correspond to the electrode connection structure 120 of FIGS. 1 to 4.

According to some example embodiments, the landing pad LP may include a conductive material. The landing pad LP may include, for example, at least one of doped polysilicon, conductive metal nitride, conductive metal silicon nitride, metal carbonitride, conductive metal silicide, conductive metal oxide, 2D material, metal, and metal alloy.

According to some example embodiments, the capacitor structure CAP may be disposed on the landing pad LP. The capacitor structure CAP may be electrically connected to the channel pattern CP through the landing pad LP.

According to some example embodiments, descriptions of the first electrode 210, the dielectric film 220, and the second electrode 230 included in the capacitor structure CAP may be substantially identical to the description with reference to FIGS. 1 to 4.

According to some example embodiments, the first electrode 210 may be surrounded by the dielectric film 220 and the capping film 250. The first electrode 210 may not be in contact with and may be spaced apart from the supporter structure 130 with the dielectric film 220 in between. The second electrode 230 may be in contact with the supporter structure 130 and may fill the space between the first supporter 131 and the second supporter 132. The dielectric film 220 may not overlap with the supporter structure 130 in the first direction D1 and may extend in the first direction D1 along the first electrode 210. In addition, the capping film 250 may overlap with the first electrode 210 in the first direction D1 and be disposed between the first electrode 210 and the second electrode 230.

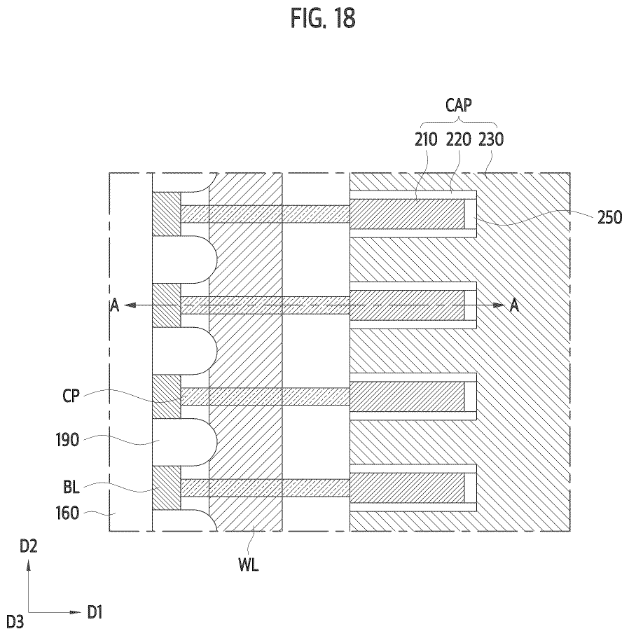

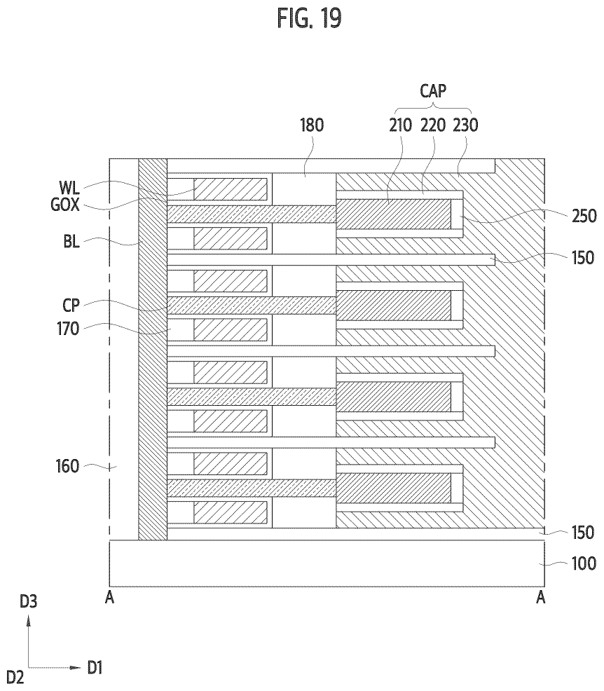

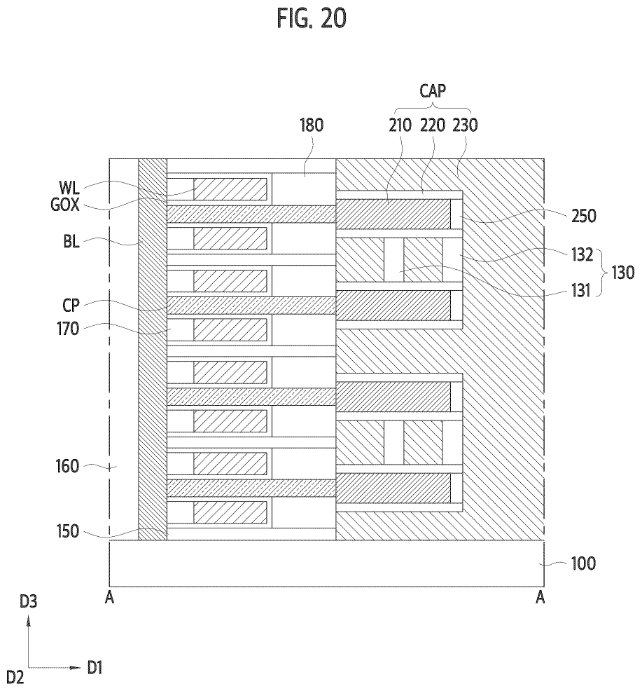

FIG. 18 is a schematic layout diagram for illustrating a semiconductor device according to still other example embodiments. FIG. 19 is an example diagram showing a cross-section taken along line A-A of FIG. 18. FIG. 20 is another example diagram showing a cross-section taken along line A-A of FIG. 18 to illustrate a semiconductor device according to yet other example embodiments.

Referring to FIGS. 18 and 19, the semiconductor device according to still other example embodiments may include a vertical insulating pattern 160, the word lines WL, the bit lines BL, the channel pattern CP, and the capacitor structure CAP.

According to some example embodiments, the substrate 100 may be a semiconductive substrate, such as a bulk silicon substate or a silicon-on-insulator (SOI) substrate. Alternatively, the substrate 100 may be a silicon substrate and/or may include, but is not limited to, other materials such as silicon germanium, silicon germanium on insulator (SGOI), indium antimonide, lead telluride, indium arsenide, indium phosphide, gallium arsenide, gallium antimonide, and/or a combination thereof.

According to some example embodiments, the vertical insulating pattern 160 may extend in the third direction D3 on the substrate 100. The vertical insulating pattern 160 may cover a sidewall of the bit lines BL. The vertical insulating pattern 160 may include, for example, at least one of a silicon oxide film, a silicon nitride film, a silicon oxynitride film, a carbon-containing silicon oxide film, a carbon-containing silicon nitride film, a carbon-containing silicon oxynitride film, and/or a combination thereof.

According to some example embodiments, a plurality of interlayer insulating films 150 and the plurality of word lines WL may be stacked on the substrate 100 in the third direction D3. The plurality of interlayer insulating films 150 and the plurality of word lines WL may be stacked alternately on the substrate 100. For example, two word lines WL may be disposed between two interlayer insulating films 150 adjacent in the third direction D3.

According to some example embodiments, the word lines WL may include a conductive material and may include, for example, at least one of doped polysilicon, conductive metal nitride, conductive metal silicon nitride, metal carbonitride, conductive metal silicide, conductive metal oxide, 2D material, metal, metal alloy, and/or a combination thereof.

According to some example embodiments, the interlayer insulating films 150 may electrically isolate the word lines WL adjacent in the third direction D3. The interlayer insulating films 150 may extend between the word lines WL and extend in the first direction D1 between the capacitor structures CAP. The interlayer insulating films 150 may extend between the capacitor structures CAP adjacent in the third direction D3. At least a portion of the interlayer insulating films 150 may overlap with the capacitor structure CAP in the third direction D3.

According to some example embodiments, the interlayer insulating films 150 may include an insulating material. The interlayer insulating films 150 may include, for example, at least one of a silicon oxide film, a silicon nitride film, a silicon oxynitride film, a carbon-containing silicon oxide film, a carbon-containing silicon nitride film, a carbon-containing silicon oxynitride film, and/or a combination thereof.

According to some example embodiments, the bit lines BL may extend in the third direction D3. The third direction D3 may be a direction perpendicular to a direction in which the first electrode 210 and the electrode connection structure 120 overlap (e.g. the first direction D1). In these cases, the third direction D3 may be a direction perpendicular to a surface of the substrate 100. The bit lines BL may intersect with the word lines WL. The plurality of bit lines BL may be disposed to be spaced apart from each other in the second direction D2. An element isolation pattern 190 may be disposed between the plurality of bit lines BL adjacent in the second direction D2. The bit lines BL may be connected to the channel pattern CP.

According to some example embodiments, the channel pattern CP may be stacked on the substrate 100 in the third direction D3. The channel pattern CP may be disposed between the word lines WL adjacent in the third direction D3. The channel pattern CP may extend in the first direction D1. The channel pattern CP may extend between the bit lines BL and the first electrode 210 in the first direction D1. The first direction D1 may be a direction parallel to a surface of the substrate 100. The channel pattern CP may be connected to the bit lines BL and the capacitor structure CAP. At least a portion of the channel pattern CP may include a source/drain region.

According to some example embodiments, the channel pattern CP may include a semiconductor, such as silicon-germanium (SiGe). As an example, the channel pattern CP may consist of single-crystal silicon. The channel pattern CP may include, for example, one of indium oxide, tin oxide, zinc oxide, In—Zn-based oxide (IZO), Sn-Zn-based oxide, Al—Zn-based oxide, Zn—Mg-based oxide, Sn—Mg-based oxide, In—Mg-based oxide, In—Ga-based oxide (IGO), In—Ga—Zn-based oxide (IGZO), In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, In—Lu—Zn-based oxide, In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, and In—Hf—Al—Zn-based oxide but is not limited thereto.

According to some example embodiments, a first spacer insulating pattern 170 may be disposed between the bit lines BL and the word lines WL. A second spacer insulating pattern 180 may be disposed between the word lines WL and the capacitor structure CAP. The second spacer insulating pattern 180 may be disposed between the channel pattern CP and the interlayer insulating films 150 which are adjacent in the third direction D3.

According to some example embodiments, the gate insulating film GOX may surround the word lines WL. FIG. 19 illustrates that the gate insulating film GOX surrounds the word lines WL and the first spacer insulating pattern 170, but example embodiments are not limited thereto. For example, the gate insulating film GOX may not surround the first spacer insulating pattern 170 and may surround the word lines WL.

According to some example embodiments, each of the first spacer insulating pattern 170, the second spacer insulating pattern 180, and the gate insulating film GOX may include an insulating material. For example, each of the first spacer insulating pattern 170, the second spacer insulating pattern 180, and the gate insulating film GOX may include at least one of a silicon oxide film, a silicon nitride film, a silicon oxynitride film, a carbon-containing silicon oxide film, a carbon-containing silicon nitride film, a carbon-containing silicon oxynitride film, and/or a combination thereof.

According to some example embodiments, the first electrode 210 of the capacitor structure CAP may be connected to the channel pattern CP and extend in the first direction D1. The first electrode 210 and the dielectric film 220 and the capping film 250 which surround the first electrode 210 may be disposed between the interlayer insulating films 150 adjacent in the third direction D3.

Referring to FIG. 20, the interlayer insulating films 150 may not overlap with the capacitor structure CAP in the third direction D3. The interlayer insulating films 150 may extend between the second spacer insulating patterns 180 in the first direction D1 and may not extend between the first electrodes 210.

According to some example embodiments, the supporter structure 130 supporting the first electrode 210 and the dielectric film 220 surrounding the first electrode 210 may be disposed.

Referring to FIGS. 18 to 20, descriptions of the first electrode 210, the dielectric film 220, and the second electrode 230 included in the capacitor structure CAP may be substantially identical to the description with reference to FIGS. 1 to 4. For example, the first electrode 210 may be surrounded by the dielectric film 220 and the capping film 250. The capping film 250 may overlap with the first electrode 210 in the first direction D1 and be disposed between the first electrode 210 and the second electrode 230.

While various example embodiments of the present disclosure are described in detail above, the scope of the present disclosure is not limited thereto, and it will be apparent to those of ordinary skill in the art that modifications and variations may be made without departing from the scope of the present disclosure as defined by the appended claims. In addition, the aforementioned example embodiments may be implemented with some elements removed, and each example embodiment may be implemented in combination with each other.

What is claimed is:

1. A semiconductor device comprising:
a first electrode extending in a first direction;
a capping film covering a first surface of the first electrode, the first surface intersecting with the first direction;
a dielectric film surrounding a second surface of the first electrode, the second surface intersecting with the first surface; and
a second electrode covering the capping film and the dielectric film.

2. The semiconductor device of claim 1, wherein the first electrode does not overlap with the dielectric film in the first direction.

3. The semiconductor device of claim 1, further comprising:
a supporter structure connected to the dielectric film and surrounded by the dielectric film and the second electrode.

4. The semiconductor device of claim 3, wherein the supporter structure includes a first supporter and a second supporter which are spaced apart in the first direction, and
wherein the second electrode fills a space between the first supporter and the second supporter.

5. The semiconductor device of claim 4, wherein the second electrode is in direct contact with the first supporter and the second supporter.

6. The semiconductor device of claim 3, wherein the second electrode covers a first surface of the supporter structure, the first surface of the supporter structure facing the first direction, and
wherein a second surface of the supporter structure is in contact with the dielectric film, the second surface facing a second direction, the second direction intersecting the first direction.

7. The semiconductor device of claim 1, wherein at least a portion of the capping film is surrounded by the dielectric film.

8. The semiconductor device of claim 7, wherein, in the first direction, the capping film overlaps with the first electrode and does not overlap with the dielectric film.

9. The semiconductor device of claim 7, wherein, in a second direction intersecting with the first direction, a width of the capping film and a width of the first electrode have a same width.

10. The semiconductor device of claim 1, wherein, in the first direction, the capping film overlaps with the first surface and the dielectric film.

11. The semiconductor device of claim 10, wherein, in a second direction intersecting with the first direction, a width of the capping film is greater than a width of the first electrode.

12. The semiconductor device of claim 1, wherein a length of the second surface in the first direction is greater than a width of the first surface in a second direction, the second direction intersecting with the first direction.

13. A method of fabricating a semiconductor device, the method comprising:
forming a trench penetrating a mold structure in a first direction;
forming a dielectric film on an inner sidewall of the trench;
forming a first electrode on the dielectric film within the trench;
forming a capping film covering the first electrode within the trench;
removing at least a portion of the mold structure; and
forming a second electrode on the dielectric film and the capping film.

14. The method of claim 13, wherein the forming of the dielectric film on the inner sidewall of the trench includes:
forming the dielectric film extending along a profile of the trench; and
removing a portion of the dielectric film formed on a bottom surface of the trench.

15. The method of claim 13, wherein the mold structure includes a supporter structure, and
wherein the removing of at least the portion of the mold structure includes maintaining the supporter structure.

16. The method of claim 15, wherein the forming of the second electrode includes forming the second electrode such that the second electrode covers the dielectric film, the capping film, and the supporter structure.

17. The method of claim 15, wherein the forming of the dielectric film includes forming the dielectric film to cover a surface of the supporter structure exposed to the inner sidewall of the trench.

18. The method of claim 13, wherein the forming the capping film includes forming the capping film such that at least a portion of the capping film is surrounded by the dielectric film within the trench.

19. The method of claim 13, wherein the forming of the first electrode includes forming the first electrode such that, in the first direction, a height of the first electrode is less than a height of the dielectric film within the trench.

20. A semiconductor device comprising:
a first electrode extending in a first direction;
a capping film covering a first surface of the first electrode, the first surface intersecting with the first direction;
a dielectric film covering a second surface of the first electrode, the second surface intersecting with the first surface;
a second electrode covering the capping film and the dielectric film; and
a plurality of supporters spaced apart in the first direction and connected to the dielectric film,
wherein the dielectric film separates the first electrode from the plurality of supporters,
the second electrode fills a space between the plurality of supporters, and
the plurality of supporters do not overlap with the dielectric film in the first direction.
